(19) United States
(12) Patent Application Publication
(10) Pub. No.: US 2026/0239669 A1
(43) Pub. Date: Aug. 13, 2026

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventors: KeJing Yu, Kaohsiung City (TW); Ru-Shang Hsiao, Jhubei City (TW)

(73) Assignee: Taiwan Semiconductor Manufacturing Company, Ltd., Hsinchu (TW)

(21) Appl. No.: 19/052,354

(22) Filed: Feb. 13, 2025

(51) Int. Cl. H10D 30/67; H01L 23/528; H10B 10/00; H10D 30/00; H10D 30/01; H10D 30/62; H10D 62/10; H10D 64/01; H10D 84/01; H10D 84/83

(52) U.S. Cl. CPC H10D 30/6735; H10B 10/12; H10D 30/0191; H10D 30/024; H10D 30/502; H10D 30/62; H10D 62/121; H10D 64/017; H10D 84/013; H10D 84/0149; H10D 84/0158; H10D 84/832; H10W 20/427

(57) ABSTRACT

A method includes: forming a dielectric layer on a substrate; forming an active region of a MOS device; forming a sacrificial gate structure of the MOS device; forming a source feature and a drain feature of the MOS device, wherein the drain feature is formed above the dielectric layer; replacing the sacrificial gate structure with a replacement metal gate; and forming a first backside power rail and a first backside VIA that connect to the drain feature through salicide formed in a recess in the dielectric layer; wherein the dielectric layer isolates the drain feature from the substrate.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum feature sizes are reduced, additional problems arise that should be addressed.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow chart depicting an example method of semiconductor fabrication including fabrication of multi-gate devices, in accordance with some embodiments.

FIGS. 2-4, 5A-5C,6, 7A-7B, and 8-19, are schematic diagrams of a semiconductor structure at various stages of fabrication, in accordance with some embodiments.

FIG. 20A is a top view of the example semiconductor structure.

FIG. 20B illustrates a cross-sectional schematic view of the semiconductor device taken along the X-cut line of FIG. 20A and FIG. 20C illustrates a cross-sectional schematic view of the semiconductor device taken along the Y-cut line of FIG. 20A.

FIG. 21 is a flow chart depicting an example method of semiconductor fabrication, according to various aspects of the present disclosure.

FIGS. 22-27 and 28A-28C are schematic diagrams of a semiconductor structure at various stages of fabrication, in accordance with some embodiments.

FIG. 29A is a flow diagram depicting an example method of semiconductor fabrication, in accordance with some embodiments.

FIGS. 29B-29D are schematic diagrams of a semiconductor structure at various stages of fabrication, in accordance with some embodiments.

FIG. 30A-30E are schematic diagrams illustrating an example method for forming an FFBI layer in a substrate.

FIG. 31A is a flow diagram depicting an example method of semiconductor fabrication, in accordance with some embodiments.

FIGS. 31B-31D are schematic diagrams of a semiconductor structure at various stages of fabrication, in accordance with some embodiments.

FIG. 32A is a flow diagram depicting an example method of semiconductor fabrication, in accordance with some embodiments.

FIGS. 32B-32D are schematic diagrams of a semiconductor structure at various stages of fabrication, in accordance with some embodiments.

FIG. 33A is a flow diagram depicting an example method of semiconductor fabrication, in accordance with some embodiments.

FIGS. 33B-33D are schematic diagrams of a semiconductor structure at various stages of fabrication, in accordance with some embodiments.

FIG. 34A is a flow diagram depicting an example method of semiconductor fabrication, in accordance with some embodiments.

FIGS. 34B-34D are schematic diagrams of a semiconductor structure at various stages of fabrication, in accordance with some embodiments.

FIG. 35A is a flow diagram depicting an example method of semiconductor fabrication, in accordance with some embodiments.

FIGS. 35B-35D are schematic diagrams of a semiconductor structure at various stages of fabrication, in accordance with some embodiments.

FIG. 36A is a flow diagram depicting an example method of semiconductor fabrication, in accordance with some embodiments.

FIGS. 36B-36D are schematic diagrams of a semiconductor structure at various stages of fabrication, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

It should be understood that, although the terms first, second, third etc. may be used herein to describe various elements, components, regions, layers, portions and/or sections, these elements, components, regions, layers, portions, and/or sections should not be limited by these terms. These terms are only used to distinguish one element, component, region, layer, portion or section from another region, layer, or section. Thus, a first element, component, region, layer, portion, or section discussed below could be termed a second element, component, region, layer, portion, or section without departing from the teachings of the present disclosure.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present.

In addition, the present disclosure may repeat reference numerals and/or letters in the various examples. This repetition is for the purpose of simplicity and clarity and does not in itself dictate a relationship between the various embodiments and/or configurations discussed.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

In certain embodiments herein, a “material layer” is a layer that includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material; and a layer that is a “material” includes at least 50 wt. % of the identified material, for example at least 60 wt. % of the identified material, at least 75 wt. % of the identified material, at least 90 wt. % of the identified material, at least 95 wt. % of the identified material, or at least 99 wt. % of the identified material. For example, certain embodiments, each of an aluminum layer and a layer of aluminum is a layer that is at least 50 wt. %, at least 60 wt. %, at least 75 wt. %, at least 90 wt. %, at least 95 wt. %, or at least 99 wt. % of aluminum.

It is to be understood that the phraseology or terminology herein is for the purpose of description and not of limitation, such that the terminology or phraseology of the present specification is to be interpreted by those skilled in relevant art(s) in light of the teachings herein.

The following disclosure provides many different embodiments, or examples, for implementing different features of the disclosed subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. Throughout the description herein, unless otherwise specified, the same reference numeral in different figures refers to the same or similar component formed by a same or similar method using a same or similar material(s).

While the figures illustrate various embodiments of a semiconductor device, additional features may be added in the semiconductor device depicted in the Figures and some of the features described below can be replaced, modified, or eliminated in other embodiments of the semiconductor device.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

This scaling also increases the complexity of the IC process and fabrication. For example, as Integrated Circuit (IC) technology advances to smaller technology nodes, multi-gate devices have been introduced to improve gate control by increasing gate-channel coupling, reducing off-state current, and reducing short-channel effects (SCE-CHANNEL EFFECT). A multi-gate device generally refers to a device having gate structures or portions thereof disposed over more than one side of a channel region. Fin-LIKE FIELD EFFECT transistors (FinFETs) and multi-bridge-channel (MBC) transistors are examples of multi-gate devices that have become popular and promising candidates for high performance and low leakage applications. The raised channels (ELEVATED CHANNEL) of the FinFET are gate wrapped on more than one side (e.g., gate wraps the top and sidewalls of a “fin” of semiconductor material extending from the substrate). MBC transistors have a gate structure that may extend partially or fully around the channel region to provide access to the channel region on two or more sides. Because the gate structure of the MBC transistor surrounds the channel region, the MBC transistor may also be referred to as a surrounding gate transistor (surrounding gate transistor: SGT) or a surrounding Gate (GAA) transistor. The channel region of the MBC transistor may be formed from nanowires, nanoplates, other nanostructures, and/or other suitable structures. The shape of the channel region is also given the MBC transistor alternative name, e.g. a nanoplate transistor or nanowire transistor. While existing GAA transistors are generally adequate for their intended purpose, they are not satisfactory in all respects.

The present disclosure is generally related to semiconductor devices and the fabrication thereof, and in some cases to multi-gate devices. Multi-gate devices include those transistors whose gate structures are formed on at least two-sides of a channel region. These multi-gate devices may include an n-type metal-oxide-semiconductor device or a p-type metal-oxide-semiconductor multi-gate device. Specific examples herein may be presented and referred to herein as a type of multi-gate transistor referred to as a gate-all-around (GAA) device. A GAA device includes any device that has its gate structure, or portion thereof, formed on 4-sides of a channel region (e.g., surrounding a portion of a channel region). Devices presented herein also include embodiments that have channel regions disposed in nanosheet channel(s), nanowire channel(s), bar-shaped channel(s), and/or other suitable channel configurations. Presented herein are embodiments of devices that may have one or more channel regions (e.g., nanosheets) associated with a single, contiguous gate structure. One of ordinary skill may recognize other examples of semiconductor devices that may benefit from aspects of the present disclosure.

The formation of MBC transistors includes the formation of a stack comprising a plurality of channel layers interleaved by a plurality of sacrificial layers over a substrate, wherein the sacrificial layers may be selectively removed to release the channel layers as channel members by a subsequent etching process. The top of the stack and substrate are patterned to form active regions. The patterned top of the substrate may be referred to as a mesa structure (mesa structure). A gate structure including a dielectric layer and a conductive layer is then formed to surround and overlie each of the channel members. After the source/drain features are formed, the gate structure and sacrificial layer may be replaced with a functional gate stack. However, in some cases, MBC transistors may suffer from current leakage near the mesa. For example, the functional gate stack not only surrounds channel members disposed above the substrate, but also directly engages mesa structures below those channel members, resulting in a strong leakage current flowing into the substrate.

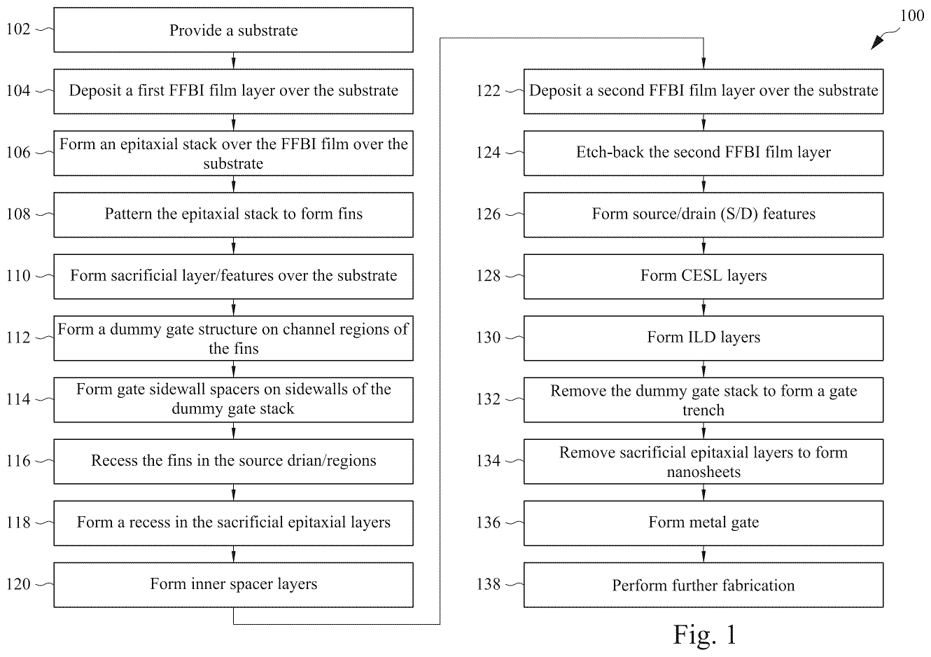

FIG. 1 is a flow chart depicting an example method 100 of semiconductor fabrication including fabrication of multi-gate devices, according to various aspects of the present disclosure. As used herein, the term “multi-gate device” is used to describe a device (e.g., a semiconductor transistor) that has at least some gate material disposed on multiple sides of at least one channel of the device. In some examples, the multi-gate device may be referred to as a GAA device having gate material disposed on four sides of at least one channel member of the device. The channel member may be referred to as “nano structure” or “nanosheet,” which is used herein to designate any material portion with nanoscale, or even microscale dimensions, and having an elongate shape, regardless of the cross-sectional shape of this portion. Thus, the term “nanostructure” or “nanosheet” as used herein designates both circular and substantially circular cross-section elongate material portions, and beam or bar-shaped material portions including for example a cylindrical in shape or substantially rectangular cross-section.

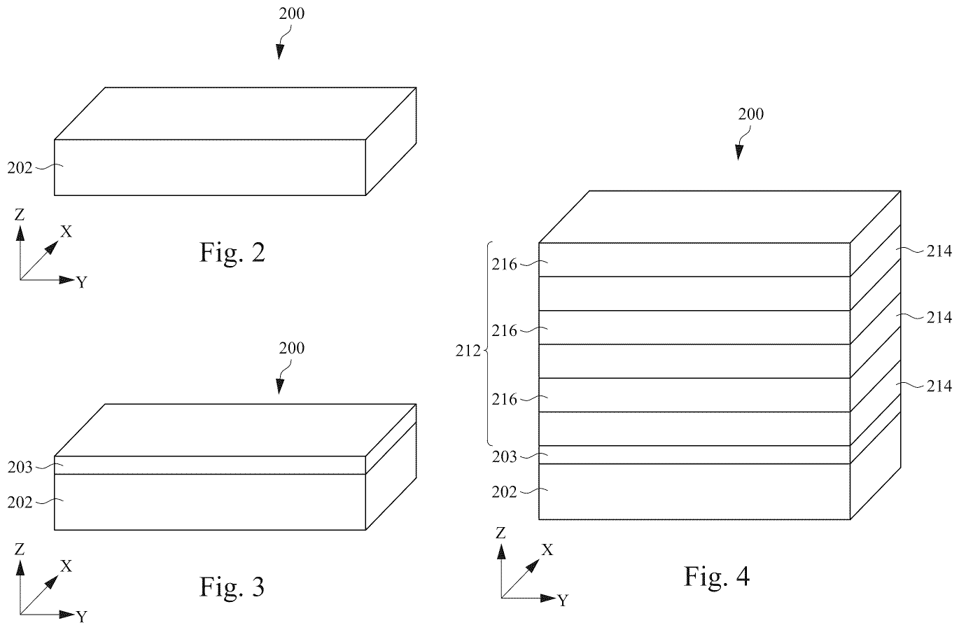

FIG. 1 is described in conjunction with FIGS. 2-4, 5A-5C,6, 7A-7B, and 8-19, which illustrate a semiconductor device 200 or structure at various stages of fabrication in accordance with some embodiments. The method 100 is merely an example and is not intended to limit the present disclosure beyond what is explicitly recited in the claims. Additional steps may be provided before, during, and after method 100, and some of the steps described can be moved, replaced, or eliminated for additional embodiments of method 100. Additional features may be added in the semiconductor device 200 depicted in the figures, and some of the features described below can be replaced, modified, or eliminated in other embodiments.

As with the other method embodiments and exemplary devices discussed herein, it is understood that parts of the semiconductor devices may be fabricated by semiconductor technology process flow, and thus some processes are only briefly described herein. Further, the exemplary semiconductor devices may include various other devices and features, such as other types of devices such as additional transistors, bipolar junction transistors, resistors, capacitors, inductors, dials, fuses, and/or other logic devices, etc., but is simplified for better understanding of concepts of the present disclosure. In some embodiments, exemplary devices include a plurality of semiconductor devices (e.g., transistors), including PFETs, NFETs, etc., which may be interconnected. Moreover, it is noted that the process steps of method 100, include any descriptions given with reference to the figures, as with the remainder of the method and exemplary figures provided in this disclosure, are merely exemplary and are not intended to be limiting beyond what is specifically recited in the claims that follow.

FIGS. 2-4, 5A-5C,6, 7A-7B, and 8-19, are schematic diagrams that illustrate an example semiconductor device structure at various stages of fabrication, in accordance with some embodiments. In some figures, some reference numbers of components or features illustrated therein may be omitted to avoid obscuring other components or features; this is for ease of depicting the figures.

At block 102, the example method 100 includes providing a substrate. Referring to the example of FIG. 2, in an embodiment of block 102, a substrate 202 is provided for forming a semiconductor device 200. In some embodiments, the substrate 202 may be a semiconductor substrate such as a silicon (Si) substrate. In some embodiments, the substrate 202 includes a single crystalline semiconductor layer on at least its surface portion. The substrate 202 may comprise a single crystalline semiconductor material such as, but not limited to Si, Ge, SiGe, GaAs, InSb, GaP, GaSb, InAlAs, InGaAs, GaSbP, GaAsSb and InP. Alternatively, the substrate 202 may include a compound semiconductor and/or an alloy semiconductor. The substrate 202 may include various layers, including conductive or insulating layers formed on a semiconductor substrate. The substrate 202 may include various doping configurations depending on design requirements. For example, different doping profiles (e.g., n wells, p wells) may be formed on the substrate 202 in regions designed for different device types (e.g., n-type field effect transistors (NFET), p-type field effect transistors (PFET)). The suitable doping may include ion implantation of dopants and/or diffusion processes. The substrate 202 has isolation features (e.g., shallow trench isolation (STI) features) interposing the regions providing different device types. Further, the substrate 202 may be strained for performance enhancement, may include a silicon-on-insulator (SOI) structure, and/or have other suitable enhancement features.

At block 104, the example method 100 includes depositing a dielectric film, referred to herein as a fully flexible bottom isolation (FFBI) film, over the substrate. Referring to the example of FIG. 3, in an embodiment of block 104, a first FFBI film layer 203 is deposited over the substrate 202. In various embodiments, the first FFBI film layer 203 can be formed from an oxide, SiN, SiC, SION, SiCN, SiCON, AlOx, ZrOx, HfOx, YOx, LiOx, and/or TaOx. In various embodiments, the first FFBI film layer 203 may be formed by a deposition method such as chemical vapor deposition (CVD). The first FFBI film layer 203 is formed over certain regions of the substrate 202, such as a logic core region and an SRAM region, and is not formed over other regions of the substrate 202, such as a logic input/output region.

At block 106, the example method 100 includes forming an epitaxial stack that includes a plurality of epitaxial layers over the FFBI film and substrate. Referring to the example of FIG. 4, in an embodiment of block 106, an epitaxial stack 212 is formed over the first FFBI film layer 203. The epitaxial stack 212 includes sacrificial epitaxial layers 214 of a first composition interposed by channel epitaxial layers 216 of a second composition. The first and second composition can be different. In an embodiment, the sacrificial epitaxial layers 214 are formed from SiGe and the channel epitaxial layers 216 are formed from silicon (Si). However, other embodiments are possible including those that provide for a first composition and a second composition having different oxidation rates and/or etch selectivity. In some embodiments, the sacrificial epitaxial layer 214 includes SiGe and the channel epitaxial layer 216 includes silicon (Si). However, other embodiments are possible including those that provide for a first composition and a second composition having different oxidation rates and/or etch selectivity. In some embodiments, the sacrificial epitaxial layer 214 includes SiGe and where the channel epitaxial layer 216 includes Si, the Si oxidation rate of the channel epitaxial layer 216 is less than the SiGe oxidation rate of the sacrificial epitaxial layer 214. It is noted that three (3) layers each of epitaxial layers 214 and 216 are illustrated in FIG. 3, which is for illustrative purposes only and not intended to be limiting beyond what is specifically recited in the claims. In various embodiments, any number of epitaxial layers can be formed in the epitaxial stack 212; the number of layers depending on the desired number of channel regions for the device 200. In some embodiments, the number of channel epitaxial layers 216 is between 1 and 5, such as 3, 4 or 5.

In some embodiments, the sacrificial epitaxial layer 214 has a thickness ranging from about 4 nm (nanometers) to about 12 nm. The sacrificial epitaxial layers 214 may be substantially uniform in thickness. In some embodiments, the channel epitaxial layer 216 has a thickness ranging from about 3 nm to about 6 nm. In some embodiments, the channel epitaxial layers 216 of the stack are substantially uniform in thickness.

As described in more detail below, the channel epitaxial layer 216 may serve as channel region(s) for a subsequently-formed multi-gate device and its thickness is chosen based on device performance considerations. The sacrificial epitaxial layer 214 may serve to reserve a spacing (or referred to as a gap) between adjacent channel region(s) for a subsequently-formed multi-gate device and its thickness is chosen based on device performance considerations.

By way of example, epitaxial growth of the epitaxial stack 212 may be performed by a molecular beam epitaxy (MBE) process, a metalorganic chemical vapor deposition (MOCVD) process, and/or other suitable epitaxial growth processes. In some embodiments, the epitaxially grown layers, such as the channel epitaxial layers 216, include the same material as the substrate 202, such as silicon (Si). In some embodiments, the epitaxially grown layers 214 and 216 include a different material than the substrate 202. As stated above, in at least some examples, the sacrificial epitaxial layer 214 includes an epitaxially grown Si₁₋ₓGeₓ layer (e.g., x is about 25~55%) and the channel epitaxial layer 216 includes an epitaxially grown Si layer. Alternatively, in some embodiments, either of the sacrificial epitaxial layers 214 and channel epitaxial layers 216 may include other materials such as germanium, a compound semiconductor such as silicon carbide, gallium arsenide, gallium phosphide, indium phosphide, indium arsenide, and/or indium antimonide, an alloy semiconductor such as SiGe, GaAsP, AlInAs, AlGaAs, InGaAs, GaInP, and/or GaInAsP, or combinations thereof. As discussed, the materials of the sacrificial epitaxial layers 214 and channel epitaxial layers 216 may be chosen based on providing differing oxidation and etch selectivity properties. In various embodiments, the epitaxial layers 214 and 216 are substantially dopant-free (i.e., having an extrinsic dopant concentration from about 0 cm⁻³ to about 1×10¹⁷ cm⁻³), where for example, no intentional doping is performed during the epitaxial growth process.

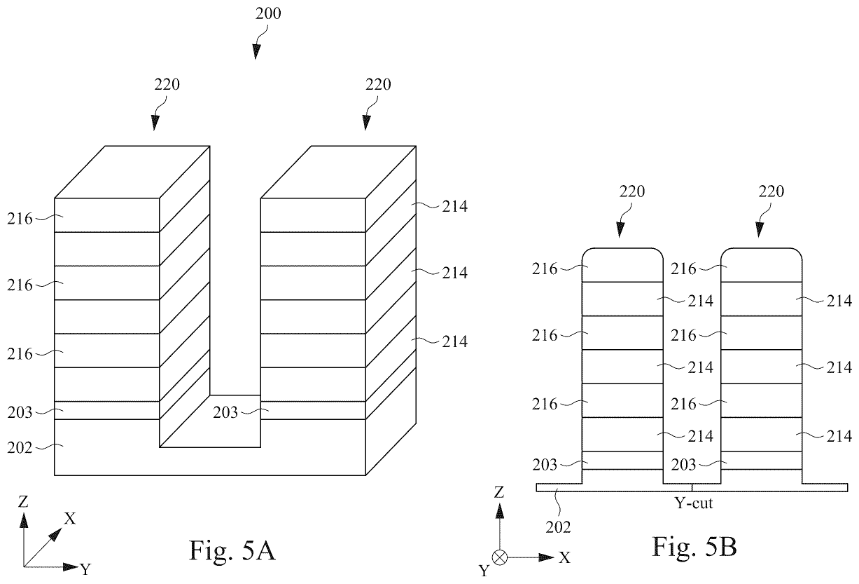

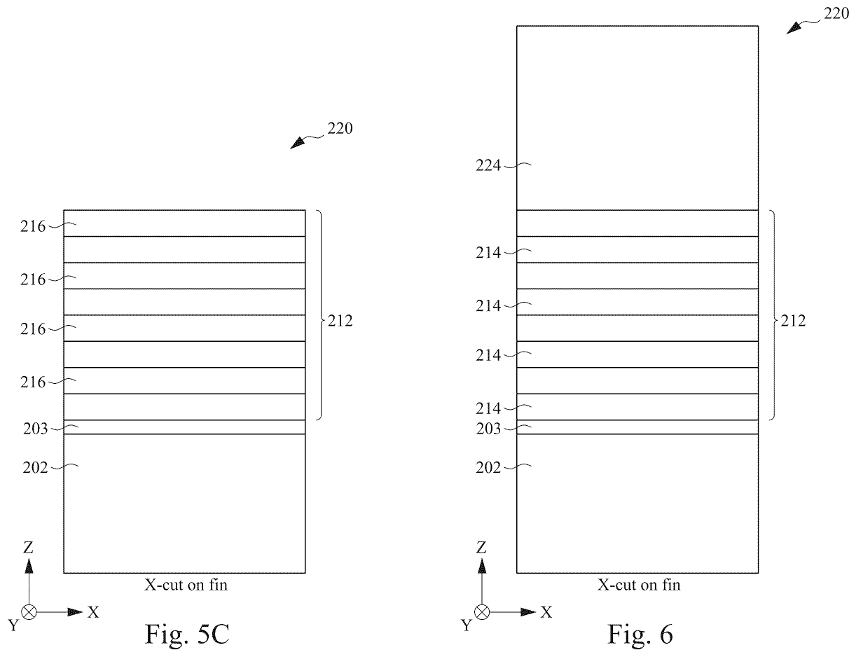

At block 108, the example method 100 includes patterning the epitaxial stack to form semiconductor fins (also referred to as fins). Referring to the example of FIGS. 5A, 5B, and 5C, in an embodiment of block 108, a plurality of fins 220 extending from the substrate 202 are formed. In various embodiments, each of the fins 220 includes an upper portion of the interleaved epitaxial layers 214 and 216 and a bottom portion protruding from the substrate 202.

The fins 220 may be fabricated using suitable processes including photolithography and etch processes. The photolithography process may include forming a photoresist layer over the substrate 202 (e.g., over the epitaxial stack 212), exposing the resist to a pattern, performing post-exposure bake processes, and developing the resist to form a masking element including the resist. In some embodiments, pattering the resist to form the masking element may be performed using an electron beam (e-beam) lithography process. The masking element may then be used to protect regions of the substrate 202, and epitaxial stack 212 formed thereupon, while an etch process forms trenches in unprotected regions through masking layer(s) such as hard mask, thereby leaving the plurality of extending fins. The trenches may be etched using a dry etch (e.g., reactive ion etching), a wet etch, and/or other suitable processes. The trenches may be filled with dielectric material forming, for example, shallow trench isolation features interposing the fins.

At block 110, the example method 100 includes forming one or more sacrificial layers/features over the substrate. Referring to the example of FIG. 6, in an embodiment of block 110, a sacrificial gate dielectric layer (not shown) is blanket deposited over a stop layer 222, which is formed over the fin 220, which is formed over the substrate 202. A sacrificial gate electrode layer 228 is then blanket deposited on the sacrificial gate dielectric layer and over the substrate 202. The sacrificial gate electrode layer 228 includes silicon such as polycrystalline silicon or amorphous silicon. The thickness of the sacrificial gate dielectric layer is in a range from about 1 nm to about 5 nm in some embodiments. The thickness of the sacrificial gate electrode layer is in a range from about 100 nm to about 200 nm in some embodiments. In some embodiments, the sacrificial gate electrode layer is subjected to a planarization operation. The sacrificial gate dielectric layer and the sacrificial gate electrode layer 228 may be deposited using CVD, including LPCVD and PECVD, PVD, ALD, or other suitable processes.

At block 112, the example method 100 includes patterning the one or more sacrificial layers/features to form a dummy gate structure on channel regions of the fins. Referring to the example of FIGS. 7A and 7B, in an embodiment of block 112, a sacrificial gate structure 224 is formed over portions of the fins 220 which are to be channel regions. The sacrificial gate structure 224 defines the channel regions of a GAA device. The sacrificial gate structure 224 includes a sacrificial gate dielectric layer and a sacrificial gate electrode layer 228. The sacrificial gate structure 224 is formed by forming a mask layer over the sacrificial gate electrode layer. The mask layer may include a pad silicon oxide layer and a silicon nitride mask layer. Subsequently, a patterning operation is performed on the mask layer and sacrificial gate dielectric and electrode layers are patterned into the sacrificial gate structure 224. By patterning the sacrificial gate structure 224, the fins 220 are partially exposed on opposite sides of the sacrificial gate structure 224, thereby defining source/drain (S/D) regions. In this disclosure, a source and a drain are interchangeably used, and the structures thereof are substantially the same.

The sacrificial gate structure 224 is subsequently removed as discussed with reference to block 132 of the method 100 and will be replaced by a final gate stack at a subsequent processing stage of the device 200. In particular, the sacrificial gate structure 224 is replaced at a later processing stage by a high-K dielectric layer (HK) and metal gate electrode (MG) as discussed below.

At block 114, the example method 100 includes forming gate sidewall spacers on sidewalls of the sacrificial gate structure. Referring to the example of FIG. 8, in an embodiment of block 114, gate sidewall spacers 232 are formed on sidewalls of the sacrificial gate structure 224. In various embodiments, the gate sidewall spacers 232 may include a dielectric material such as silicon oxide (SiOₓ), silicon nitride (SiN), silicon carbide (SiC), silicon oxynitride (SiON), SiCN films, silicon oxycarbide (SiOC), Silicon oxycarbonitride (SiOCN) films, and/or combinations thereof. In some embodiments, the gate sidewall spacers 232 include multiple layers, such as main spacer walls, liner layers, and the like. By way of example, the gate sidewall spacers 232 may be formed by depositing a dielectric material layer over the sacrificial gate structure 224 using processes such as, a CVD process, a sub atmospheric CVD (SACVD) process, a flowable CVD process, an ALD process, a PVD process, or other suitable process. In some embodiments, the deposition of the dielectric material layer is followed by an etching-back (e.g., anisotropically) process to expose portions of the fin 220 adjacent to and not covered by the sacrificial gate structure 224 (e.g., S/D regions). The dielectric material layer may remain on the sidewalls of the sacrificial gate structure 224 as gate sidewall spacers 232. In some embodiments, the etching-back process may include a wet etch process, a dry etch process, a multiple-step etch process, and/or a combination thereof. The gate sidewall spacers 232 may have a thickness ranging from about 5 nm to about 20 nm.

At block 116, the example method includes recessing the fins in the source drain/regions. Referring to the example of FIG. 9, in an embodiment of block 116, the fin 220 is recessed in the source drain/regions. The stacked epitaxial layers 214 and 216 are etched down at the S/D regions to form a recess 234. In various embodiments, the recessing is performed by a suitable etching process, such as a dry etching process, a wet etching process, or an RIE process. Dry etching may be implemented using an etchant including a bromine-containing gas (e.g., HBr and/or CHBR3), a fluorine-containing gas (e.g., CF₄, SF₆, CH₂F₂, CHF₃, and/or C₂F₆), other suitable gases, or combinations thereof.

At block 118, the example method 100 includes forming a recess in the sacrificial epitaxial layers (e.g., SiGe) of the epitaxial stack. Referring to the example of FIG. 10, in an embodiment of block 118, the sacrificial epitaxial layers 214 have been etched back forming sacrificial epitaxial layer recesses 235 bounded on the top and bottom by channel epitaxial layers 216 and laterally by the recessed sacrificial epitaxial layers 214. The sacrificial epitaxial layers 214 can be selectively etched by using a wet etchant such as, but not limited to, ammonium hydroxide (NH₄OH), tetramethylammonium hydroxide (TMAH), ethylenediamine pyrocatechol (EDP), or potassium hydroxide (KOH) solutions. Alternatively, at block 118 lateral ends of the sacrificial epitaxial layers 214 that are exposed in the recess 234 may be selectively oxidized to increase the etch selectivity between the epitaxial layers 214 and 216. In some examples, the oxidation process may be performed by exposing the device 200 to a wet oxidation process, a dry oxidation process, or a combination thereof.

At block 120, the example method 100 Includes forming an inner spacer layer in the sacrificial epitaxial layer recesses. Forming the inner spacer layer may include depositing inner spacer material of a first material type in the sacrificial epitaxial layer recesses, and trimming the inner spacer layers (e.g., via etching operations). Referring to the example of FIG. 11, in an embodiment of block 120, inner spacer layers 238 are formed in the sacrificial epitaxial layer recesses 235. The inner spacer layers 238 may be formed from silicon oxides, silicon nitrides, silicon carbides, silicon carbide nitride, silicon oxide carbide, silicon carbide oxynitride, and/or other suitable dielectric materials. In some embodiments, the inner spacer layer 238 is deposited as a conformal layer. The inner spacer layers 238 can be formed by ALD or any other suitable method. In various embodiments, the inner spacer layers 238 are formed from the same material as the gate sidewall spacers 232. In various embodiments, the gate sidewall spacers 232 and the inner spacer layers 238 are formed from SiOCN.

At block 122, the example method 100 Includes forming a second FFBI film layer over the semiconductor structure. Forming the second FFBI film layer may include depositing the second FFBI layer using a CVD process. Referring to the example of FIG. 12, a second FFBI film layer 205 is formed over the semiconductor structure 200. By way of example, the second FFBI film layer 205 may be formed by depositing a material of the same composition as the first FFBI film layer 203 over the first FFBI film layer 203 in the recess 234, the top of the sacrificial gate structure 224, the top and sidewalls of the gate sidewall spacers 232, sidewalls of the channel epitaxial layers 216, and sidewalls of the inner spacer layers 238 using processes, such as a CVD process, a sub atmospheric CVD (SACVD) process, a flowable CVD process, an ALD process, a PVD process, or other suitable process.

At block 124, the example method 100 includes etching-back the second FFBI film layer to a top level of the bottom sacrificial epitaxial layer. In various embodiments, etching-back the second FFBI film layer may involve an isotropic etching process. Referring to the example of FIG. 13, in an embodiment of block 124, the second FFBI film layer 205 has been etched-back in the recess 234 to a height equal to the height of the top level of the bottom sacrificial epitaxial layer 214. Also, the second FFBI film layer 205 has been removed from the top of the sacrificial gate structure 224, the top and sidewalls of the gate sidewall spacers 232, sidewalls of the channel epitaxial layers 216, and sidewalls of the inner spacer layers 238. In some embodiments, the etching-back process may include a wet etch process, a dry etch process, a multiple-step etch process, and/or a combination thereof. The deposition and etching-back of the second FFBI film layer 205 results in an FFBI film layer 207 made up of the first FFBI film layer 203 and the remaining portions of the second FFBI film layer 205. The FFBI film layer 207 comprises a first depth below a source feature and the drain feature (e.g., depth the first FFBI film layer 203 plus the depth of the second FFBI film layer 205) that is larger than a second depth of the FFBI film layer 207 below a channel region of the MOS device (e.g., depth of the first FFBI film layer 203).

At block 126, the example method 100 includes forming source/drain (S/D) features. Forming the S/D features may involve depositing pure silicon in the recess 234 in the source drain/regions. In various embodiments, recessing the fins in the S/D regions may involve over etching the fins in the S/D regions wherein some of the substrate 202 below the height level of the bottom sacrificial epitaxial layer 214 is removed to prevent SiGe residue. Pure Si may be deposited in the recess 234 to raise the height of the substrate 202 below the recess 234 to the height level of the bottom sacrificial epitaxial layer 214.

Referring to the example of FIG. 14, in an embodiment of block 126, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the sacrificial epitaxial layers 214 by the inner spacer layers 238.

At block 128, the example method 100 includes forming a CESL layer. Referring to the example of FIG. 15, in an embodiment of block 124, a CESL layer 242 is formed over the S/D features 240. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 242 is formed from SiN.

At block 130, the example method 100 includes forming an ILD layer. Referring to the example of FIG. 16, in an embodiment of block 130, a first interlayer dielectric (ILD0) layer 244 is formed over the CESL layer 242. The ILD0 layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD0 layer 244 may be formed by PECVD, flowable CVD (FCVD), or other suitable methods. In some embodiments, forming the ILD0 layer 244 further includes performing a CMP process to planarize a top surface of the device 200, such that the top surfaces of the sacrificial gate structure 224 are exposed.

At block 132, the example method 100 includes removing the dummy gate stack to form a gate trench. Referring to the example of FIG. 17, in an embodiment of block 132, the sacrificial gate structure 224 has been removed to form a gate trench 254. The gate trench 254 exposes the fin 220 in the channel region(s). The ILD0 layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD0 layer 244 is an oxide, a wet etchant such as a TMAH solution can be used to selectively remove the sacrificial gate electrode layer. The sacrificial gate dielectric layer is thereafter removed using plasma dry etching and/or wet etching.

At block 134, the example method 100 includes removing the sacrificial epitaxial layers to form nanosheets. Referring to the example of FIG. 18, in an embodiment of block 134, sacrificial epitaxial layers 214 have been removed thereby releasing channel members from the channel region of the GAA device. In the illustrated embodiment, channel members are channel epitaxial layers 216 in the form of nanosheets. In various embodiments, the channel epitaxial layers 216 include silicon, and the sacrificial epitaxial layers 214 include silicon germanium. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

At block 136, the example method 100 includes forming metal gate structures. Referring to the example of FIG. 19, in an embodiment of block 136, a gate structure 260 is formed. In various embodiments, the gate structure 260 is the gate of a multi-gate transistor. In various embodiments, the gate structure 260 is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layer. The high-K metal gate structures may include additional material layers.

At block 138, the example method 100 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

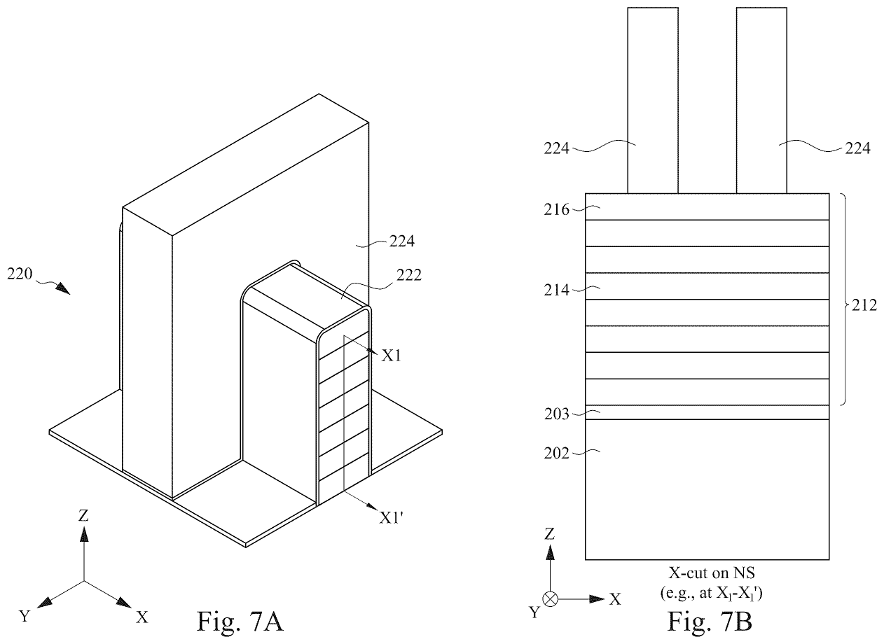

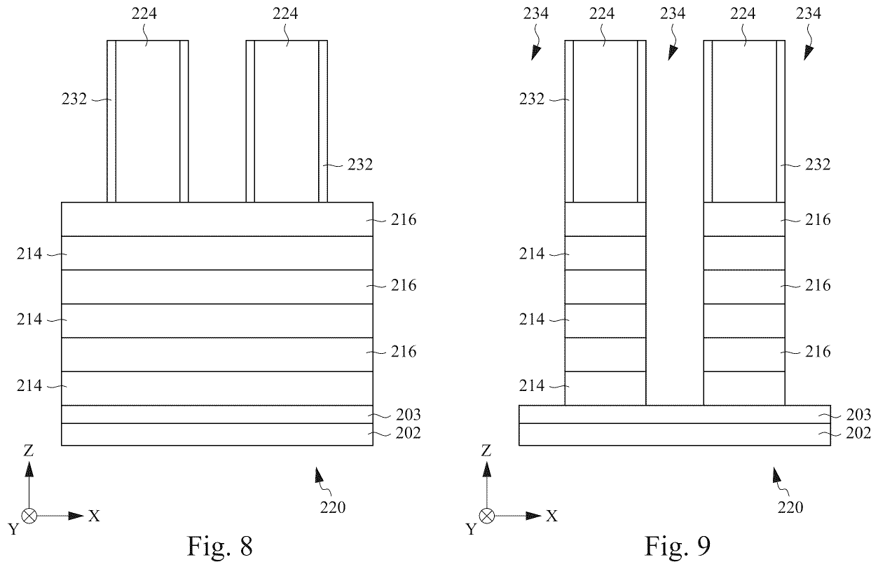

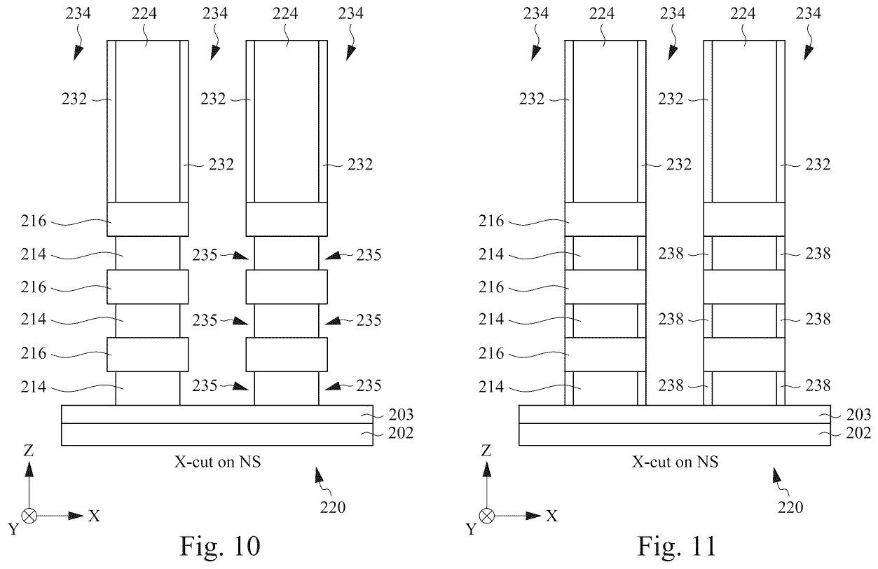

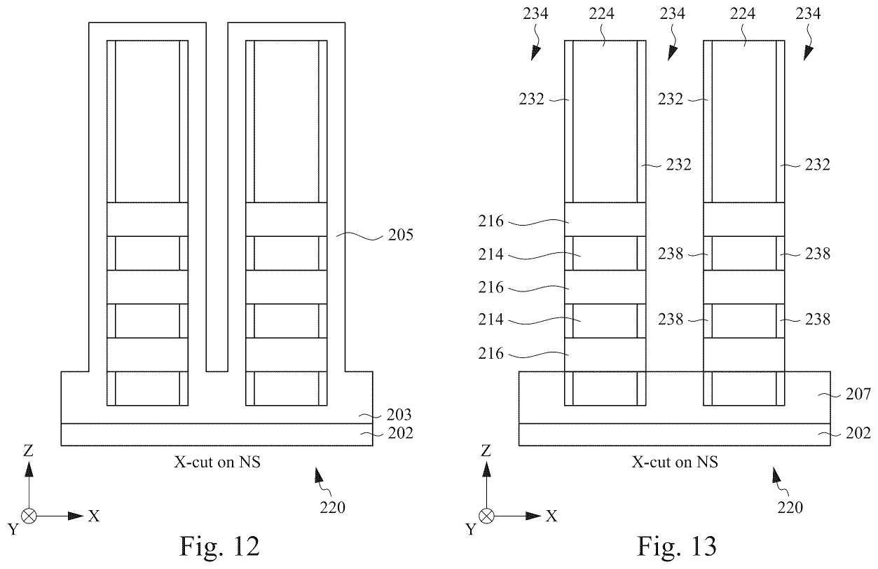

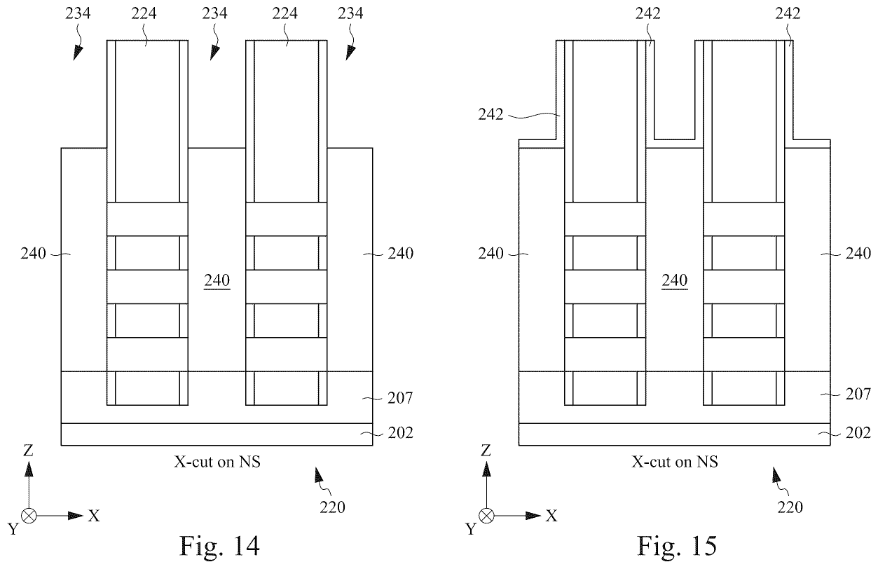

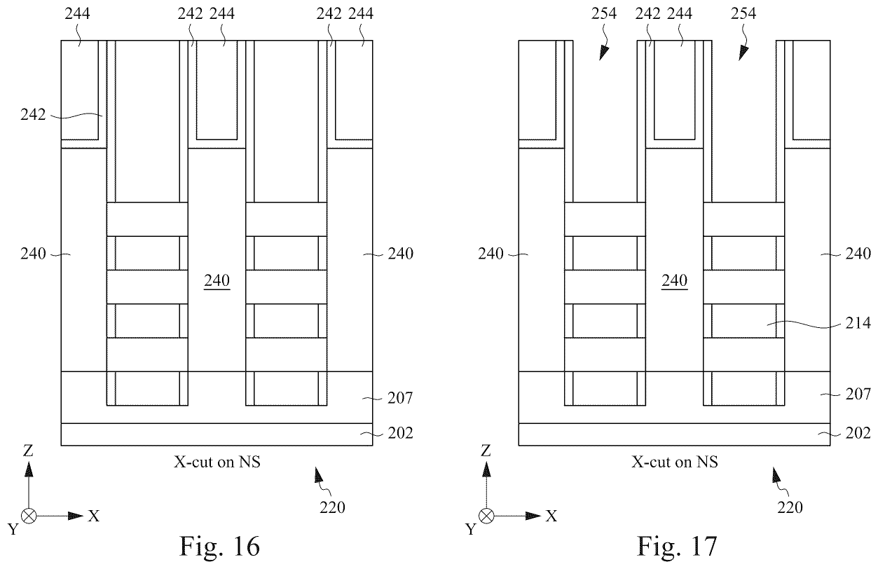

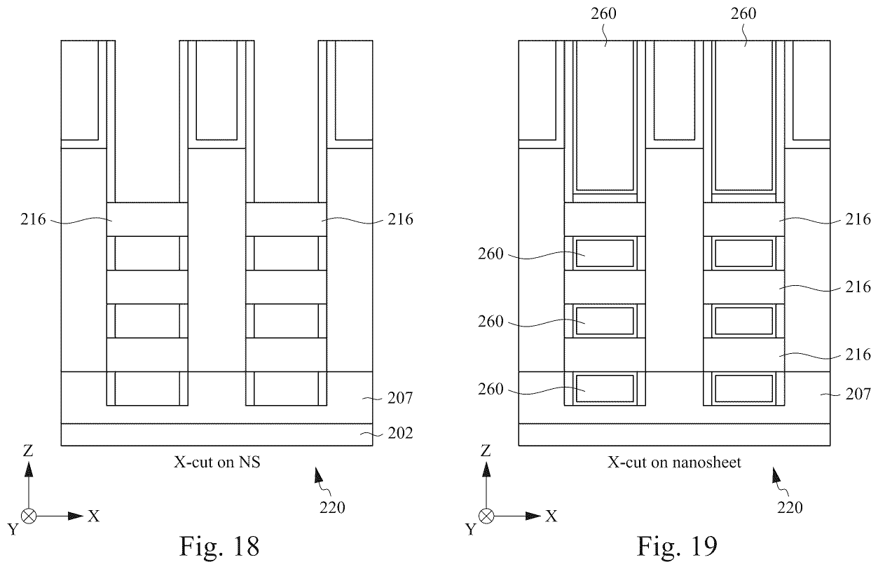

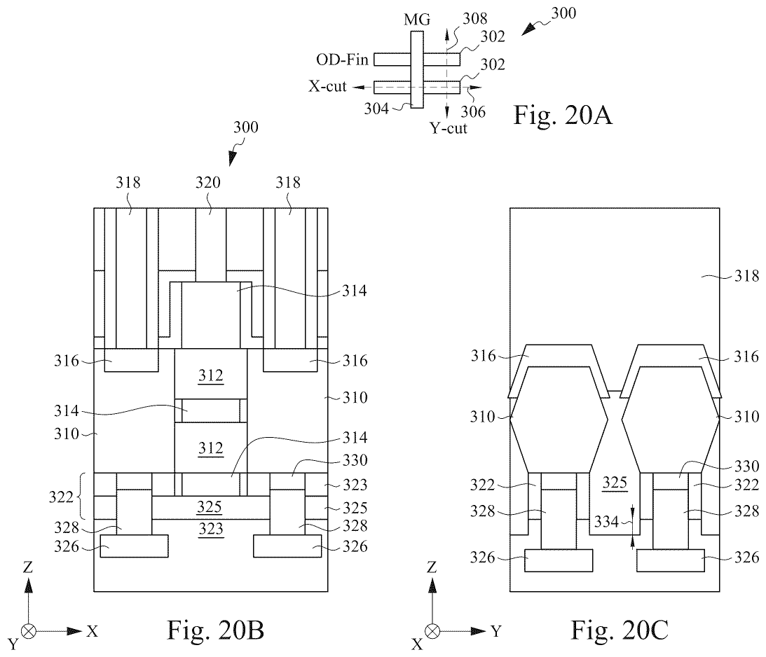

Referring to the example of FIGS. 20A-20C, in an embodiment of block 138, an example structure 300 formed during further fabrication is illustrated. FIG. 20A is a top view of the example semiconductor structure 300. Shown are a plurality of fins 302 and a metal gate 304 formed over portions of the fins 302. FIG. 20A also illustrates an X-cut line 306 and a Y-cut line 308.

FIG. 20B illustrates a cross-sectional schematic view of the semiconductor device 300 taken along the X-cut line 306 and FIG. 20C illustrates a cross-sectional schematic view of the semiconductor device 300 taken along the Y-cut line 308. The example semiconductor device 300 includes S/D regions 310, channel regions 312 disposed between the S/D regions 310, metal gate structures 314 disposed around the channel regions 312, salicide regions 316 on top portions of the S/D regions 310, metal drain contacts 318 disposed above the salicide regions 316, a metal gate contact 320 disposed above the metal gate structures 314, an FFBI film layer 322 (e.g., FFBI film layer 207) disposed under the S/D regions 310 and metal gate structures 314, and a substrate 324 on which the FFBI film layer 322 is formed. An STI feature 325 (silicon trench isolation feature) is shown between the S/D regions 310. The FFBI film layer 322 comprises a first FFBI film layer 323 (e.g., first FFBI film layer 203) and a second FFBI film layer 325 (e.g., second FFBI film layer 205).

Current MOS gates may encounter MESA leakage current from source to drain through a substrate, may have parasitic capacitance of C_{gd} between the bottom metal gate structure and the drain that can influence the effective capacitance of the device, and the bottom channel region may have worser gate control than other channel regions. The FFBI film layer 322 is a dielectric film formed at the bottom MG 314 and bottom of the S/D regions 310 that isolates S/D regions 310 from the substrate 324. Hence, the FFBI film layer 322 can eliminate MESA leakage and reduce effective capacitance.

In some embodiments, further processing includes providing a backside power rail 326 and a backside VIA 328 for connecting the backside power rail 326 to the S/D regions 310. In these embodiments, the FFBI film layer 322 can function as an etch stop layer to prevent damage to the S/D regions 310 when salicide regions 330 are formed on bottom regions of the S/D regions 310.

Forming salicide regions 330 may involve depositing one or more metals into a recess in the FFBI film layer 322, performing an annealing process to the device 300 to cause reaction between the one or more metals and the S/D features 310 to produce the salicide regions 330, and removing un-reacted portions of the one or more metals, leaving the salicide regions 330 in the recess. The one or more metals may include titanium (Ti), tantalum (Ta), tungsten (W), nickel (Ni), platinum (Pt), ytterbium (Yb), iridium (Ir), erbium (Er), cobalt (Co), or a combination thereof (e.g., an alloy of two or more metals) and may be deposited using CVD, PVD, ALD, or other suitable methods.

In an embodiment, providing a backside power rail 326 and a backside VIA 328 for connecting the backside power rail 326 to the S/D regions 310 may include forming a first recess in the FFBI film layer 322, forming salicide in the first recess, forming a first backside VIA 328 through the first recess that connects to a drain feature 310 through the salicide formed in the first recess, and forming a first backside power rail 326 that connects to the first backside VIA 328. Providing a backside power rail 326 and a backside VIA 328 for connecting the backside power rail 326 to the S/D regions 310 may also include forming a second recess in the FFBI film layer 322, forming salicide in the second recess, forming a second backside VIA 328 through the second recess that connects to a source feature 310 through the salicide formed in the second recess, and forming a second backside power rail 326 that connects to a second backside VIA 328.

In various embodiments, the FFBI film layer 322 may not be employed for I/O (input/output) devices or when the spacing between S/D regions are greater than 70 nm (nanometers). In various embodiments, the height of the FFBI film layer 322 may be greater than 5 nm when used with SRAM transistors. In various embodiments, the height of the FFBI film layer 322 may be greater than 10 nm when used with a core device. In various embodiments, an STI-to-FFBI gap 334 may between 0 to approximately 10 nm. In various embodiments, the FFBI film layer 322 may be formed from an oxide, SiN, SiON, SiCN, SiCON, AIOx, ZrOx, HfOx. Although shown with respect to MOS device of GAA type, the novel FFBI can also be applied on MOS device of FinFET and/or Planar type.

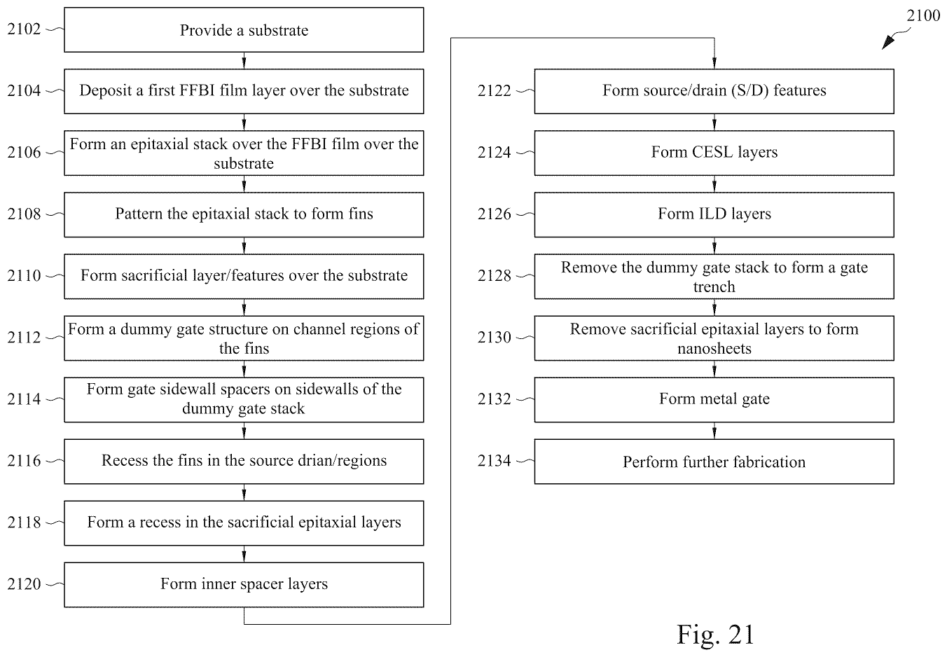

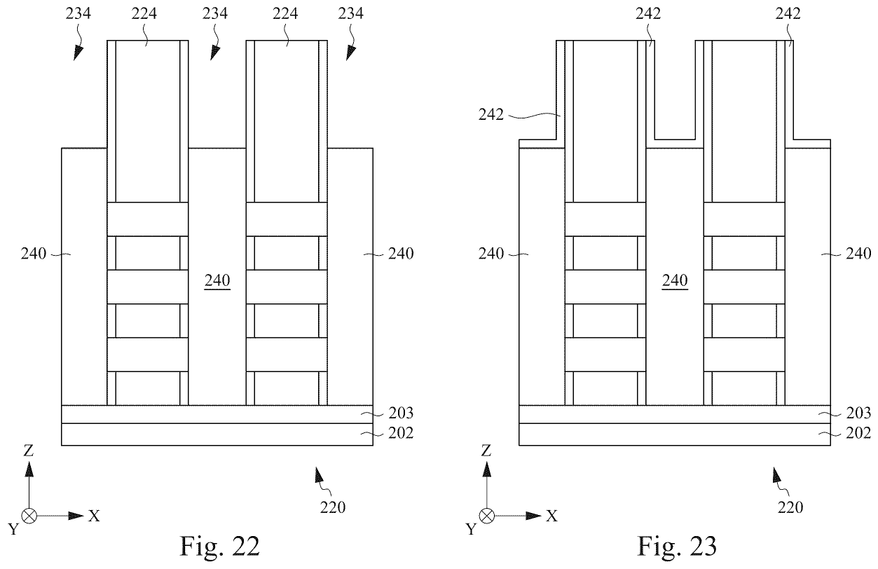

FIG. 21 is a flow chart depicting an example method 2100 of semiconductor fabrication including fabrication of multi-gate devices, according to various aspects of the present disclosure. FIG. 21 is described in conjunction with FIGS. 22-27 and 28A-28C, which illustrate a semiconductor device or structure at various stages of fabrication in accordance with some embodiments. The method 2100 is merely an example and is not intended to limit the present disclosure beyond what is explicitly recited in the claims. Additional steps may be provided before, during, and after method 2100, and some of the steps described can be moved, replaced, or eliminated for additional embodiments of method 2100. Additional features may be added in the semiconductor device depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 2102, the example method 2100 includes providing a substrate. This block is similar to block 102 of method 100 and reference is made to the corresponding description of block 102 for example description of block 2102.

At block 2104, the example method 2100 includes depositing a dielectric film, referred to herein as a fully flexible bottom isolation (FFBI) film, over the substrate. This block is similar to block 104 of method 100 and reference is made to the corresponding description of block 104 for example description of block 2104.

At block 2106, the example method 2100 includes forming an epitaxial stack that includes a plurality of epitaxial layers over the FFBI film and substrate. This block is similar to block 106 of method 100 and reference is made to the corresponding description of block 106 for example description of block 2106.

At block 2108, the example method 2100 includes patterning the epitaxial stack to form semiconductor fins (also referred to as fins). This block is similar to block 108 of method 100 and reference is made to the corresponding description of block 108 for example description of block 2108.

At block 2110, the example method 2100 includes forming one or more sacrificial layers/features over the substrate. This block is similar to block 110 of method 100 and reference is made to the corresponding description of block 110 for example description of block 2110.

At block 2112, the example method 2100 includes patterning the one or more sacrificial layers/features to form a dummy gate structure on channel regions of the fins. This block is similar to block 112 of method 100 and reference is made to the corresponding description of block 112 for example description of block 2112.

At block 2114, the example method 2100 includes forming gate sidewall spacers on sidewalls of the sacrificial gate structure. This block is similar to block 114 of method 100 and reference is made to the corresponding description of block 114 for example description of block 2114.

At block 2116, the example method includes recessing the fins in the source drain/regions. This block is similar to block 116 of method 100 and reference is made to the corresponding description of block 116 for example description of block 2116.

At block 2118, the example method 2100 includes forming a recess in the sacrificial epitaxial layers (e.g., SiGe) of the epitaxial stack. This block is similar to block 118 of method 100 and reference is made to the corresponding description of block 118 for example description of block 2118.

At block 2120, the example method 2100 Includes forming an inner spacer layer in the sacrificial epitaxial layer recesses. This block is similar to block 120 of method 100 and reference is made to the corresponding description of block 120 for example description of block 2120.

Method 2100 differs from method 100 in that method 2100 does not include providing a second FFBI film layer. Method 2100 continues at block 2122, which includes forming source/drain (S/D) features. This block is similar to block 126 of method 100 and reference is made to the corresponding description of block 126 for example description of block 2122.

Referring to the example of FIG. 22, in an embodiment of block 2122, epitaxial S/D features 240 are formed in recess 234. In some embodiments, the epitaxial S/D features 240 include silicon for NFETs and SiGe for PFETs. In some embodiments, the epitaxial S/D features 240 are formed by an epitaxial growth method using CVD, ALD, or molecular beam epitaxy (MBE). The epitaxial S/D features 240 are formed in contact with the channel epitaxial layers 216 and separated from the sacrificial epitaxial layers 214 by the inner spacer layers 238.

At block 2124, the example method 2100 includes forming a CESL layer. Referring to the example of FIG. 23, in an embodiment of block 2124, a CESL layer 242 is formed over the S/D features 240. The CESL layer 242 may comprise silicon nitride, silicon oxynitride, silicon nitride with oxygen (O) or carbon (C) elements, and/or other materials; and may be formed by CVD, PVD (physical vapor deposition), ALD, or other suitable methods. In various embodiments, the CESL layer 242 is formed from SiN.

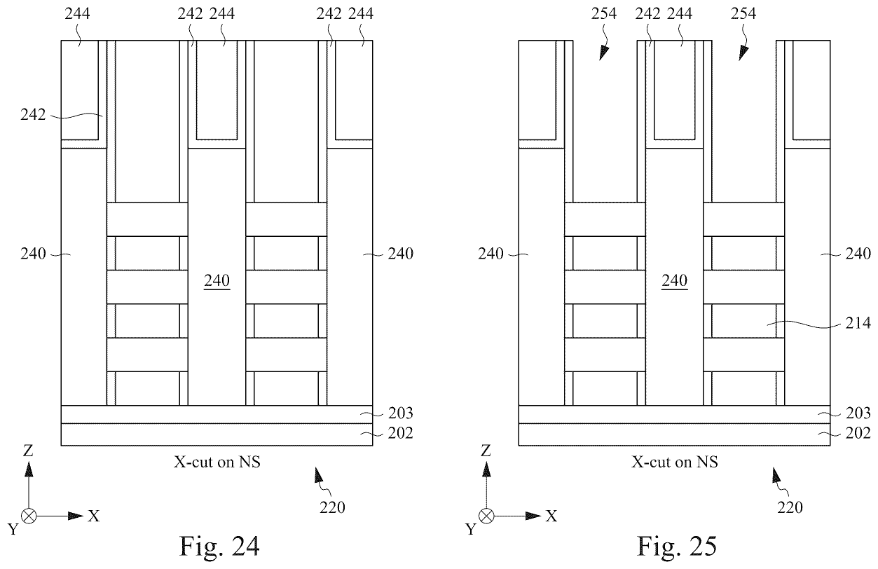

At block 2126, the example method 2100 includes forming an ILD layer. Referring to the example of FIG. 24, in an embodiment of block 2126, a first interlayer dielectric (ILD0) layer 244 is formed over the CESL layer 242. The ILD0 layer 244 may comprise tetraethylorthosilicate (TEOS) oxide, un-doped silicate glass, or doped silicon oxide such as borophosphosilicate glass (BPSG), fused silica glass (FSG), phosphosilicate glass (PSG), boron doped silicon glass (BSG), and/or other suitable dielectric materials. The ILD0 layer 244 may be formed by PECVD, flowable CVD (FCVD), or other suitable methods. In some embodiments, forming the ILD0 layer 244 further includes performing a CMP process to planarize a top surface of the device 200, such that the top surfaces of the sacrificial gate structure 224 are exposed.

At block 2128, the example method 2100 includes removing the dummy gate stack to form a gate trench. Referring to the example of FIG. 25, in an embodiment of block 2128, the sacrificial gate structure 224 has been removed to form a gate trench 254. The gate trench 254 exposes the fin 220 in the channel region(s). The ILD0 layer 244 and the CESL layer 242 protects the epitaxial S/D features 240 during the removal of the sacrificial gate structure 224. The sacrificial gate structure 224 can be removed using plasma dry etching and/or wet etching. When the sacrificial gate electrode layer is polysilicon and the ILD0 layer 244 is an oxide, a wet etchant such as a TMAH solution can be used to selectively remove the sacrificial gate electrode layer. The sacrificial gate dielectric layer is thereafter removed using plasma dry etching and/or wet etching.

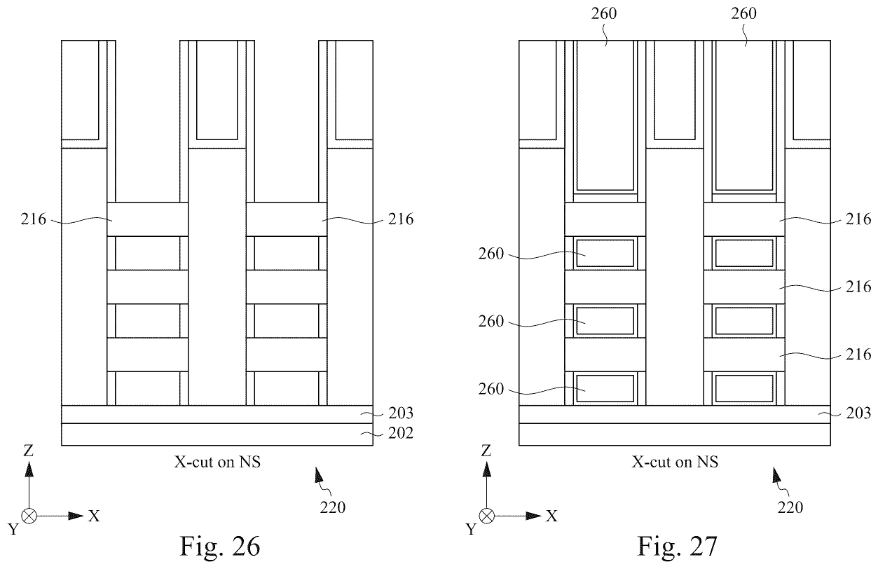

At block 2130, the example method 100 includes removing the sacrificial epitaxial layers to form nanosheets. Referring to the example of FIG. 26, in an embodiment of block 2130, sacrificial epitaxial layers 214 have been removed thereby releasing channel members from the channel region of the GAA device. In the illustrated embodiment, channel members are channel epitaxial layers 216 in the form of nanosheets. In various embodiments, the channel epitaxial layers 216 include silicon, and the sacrificial epitaxial layers 214 include silicon germanium. In various embodiments, the plurality of sacrificial epitaxial layers 214 were selectively removed via a selective removal process that included oxidizing the plurality of sacrificial epitaxial layers 214 using a suitable oxidizer, such as ozone. Thereafter, the oxidized sacrificial epitaxial layers 214 were selectively removed via a dry etching process, for example, by applying an HCl gas at a temperature of about 500 degrees Celsius to about 700 degrees Celsius, or applying a gas mixture of CF₄, SF₆, and CHF₃.

At block 2132, the example method 2100 includes forming metal gate structures. Referring to the example of FIG. 27, in an embodiment of block 2132, a gate structure 260 is formed. In various embodiments, the gate structure 260 is the gate of a multi-gate transistor. In various embodiments, the gate structure 260 is a high-K metal gate stack, however other compositions are possible. In various embodiments the high-K metal gate stack includes a gate dielectric layer that includes an interfacial layer and a high-k dielectric layer. The high-k dielectric layer wraps each of the nanosheets 216, and the interfacial layer is interposed between the high-k dielectric layer and the nanosheets 216. The interfacial layer may include a dielectric material such as silicon oxide (SiO₂) or silicon oxynitride (SiON), and may be formed by chemical oxidation, thermal oxidation, atomic layer deposition (ALD), CVD, and/or other suitable methods. The high-k dielectric layer may include hafnium oxide (HfO₂), hafnium silicon oxide (HfSiO), hafnium silicon oxynitride (HfSiON), hafnium tantalum oxide (HMO), hafnium titanium oxide (HfTiO), hafnium zirconium oxide (HfZrO), other suitable high-k dielectric materials, and/or combinations thereof. The high-k material may further be selected from metal oxides, metal nitrides, metal silicates, transition metal-oxides, transition metal-nitrides, transition metal-silicates, oxynitrides of metals, metal aluminates, zirconium silicate, zirconium aluminate, silicon oxide, silicon nitride, silicon oxynitride, zirconium oxide, titanium oxide, aluminum oxide, hafnium dioxide-alumina (HfO₂—Al₂O₃) alloy, other suitable materials, and/or combinations thereof. The high-k dielectric layer may be formed by any suitable process, such as atomic layer deposition (ALD), chemical vapor deposition (CVD), physical vapor deposition (PVD), remote plasma CVD (RPCVD), plasma enhanced CVD (PECVD), metal organic CVD (MOCVD), sputtering, plating, other suitable processes, and/or combinations thereof. In one embodiment, the gate dielectric layer is formed using a highly conformal deposition process such as ALD in order to ensure the formation of a gate dielectric layer having a uniform thickness around each channel layer. The high-K metal gate structures may include additional material layers.

At block 2134, the example method 2100 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 100, and some process steps described above may be replaced or eliminated in accordance with various embodiments of the method 100.

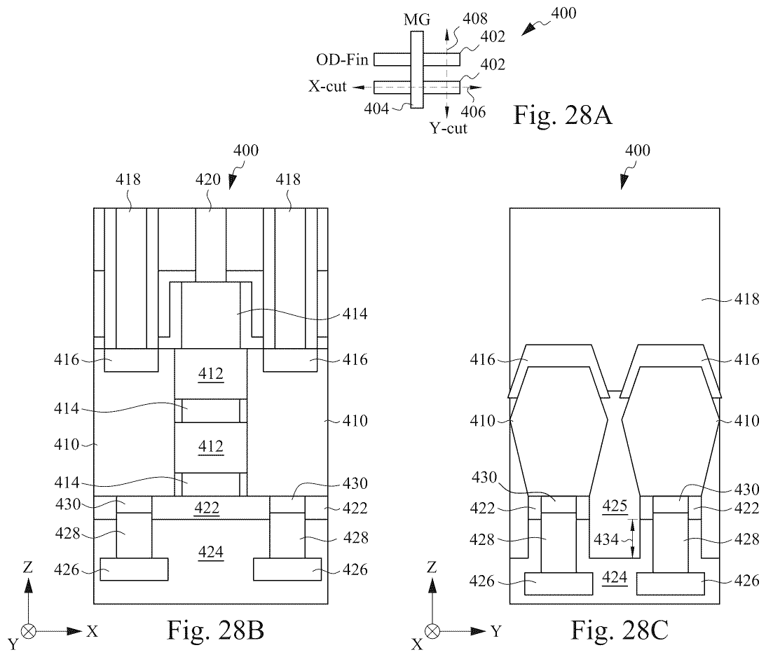

Referring to the example of FIGS. 28A-28C, in an embodiment of block 2134, an example structure 400 formed during further fabrication is illustrated. FIG. 28A is a top view of the example semiconductor structure 400. Shown are a plurality of fins 402 and a metal gate 404 formed over portions of the fins 402. FIG. 28A also illustrates an X-cut line 406 and a Y-cut line 408.

FIG. 28B illustrates a cross-sectional schematic view of the semiconductor device 400 taken along the X-cut line 406 and FIG. 28C illustrates a cross-sectional schematic view of the semiconductor device 400 taken along the Y-cut line 408. The example semiconductor device 400 includes S/D regions 410, channel regions 412 disposed between the S/D regions 410, metal gate structures 414 disposed around the channel regions 412, salicide regions 416 on top portions of the S/D regions 410, metal drain contacts 418 disposed above the salicide regions 416, a metal gate contact 420 disposed above the metal gate structures 414, an FFBI film layer 422 (e.g., FFBI film layer 207) disposed under the S/D regions 410 and metal gate structures 414, and a substrate 424 on which the FFBI film layer 422 is formed. An STI feature 425 (silicon trench isolation feature) is shown between the S/D regions 410.

Current MOS gates may encounter MESA leakage current from source to drain through a substrate, may have parasitic capacitance of C_{gd} between the bottom metal gate structure and the drain that can influence the effective capacitance of the device, and the bottom channel region may have worser gate control than other channel regions. The FFBI film layer 422 is a dielectric film formed at the bottom MG 414 and bottom of the S/D regions 410 that isolates S/D regions 410 from the substrate 424. Hence, the FFBI film layer 422 can eliminate MESA leakage and reduce effective capacitance.

In some embodiments, further processing includes providing a backside power rail 426 and a backside VIA for connecting the backside power rail 426 to the S/D regions 410. In these embodiments, the FFBI film layer 422 can function as an etch stop layer to prevent damage to the S/D regions 410 when salicide regions 430 are formed on bottom regions of the S/D regions 410.

In an embodiment, providing a backside power rail 426 and a backside VIA 428 for connecting the backside power rail 426 to the S/D regions 410 may include forming a first recess in the FFBI film layer 422, forming salicide in the first recess, forming a first backside VIA 428 through the first recess that connects to a drain feature 410 through the salicide formed in the first recess, and forming a first backside power rail 426 that connects to the first backside VIA 428. Providing a backside power rail 426 and a backside VIA 428 for connecting the backside power rail 426 to the S/D regions 410 may also include forming a second recess in the FFBI film layer 422, forming salicide in the second recess, forming a second backside VIA 428 through the second recess that connects to a source feature 410 through the salicide formed in the second recess, and forming a second backside power rail 426 that connects to a second backside VIA 428.

In various embodiments, the FFBI film layer 422 may not be employed for I/O (input/output) devices or when the spacing between S/D regions are greater than 70 nm (nanometers). In various embodiments, the height of the FFBI film layer 422 may be greater than 5 nm when used with SRAM transistors. In various embodiments, the height of the FFBI film layer 422 may be greater than 10 nm when used with a core device. In various embodiments, an STI-to-FFBI gap 434 may between 0 to approximately 10 nm. In various embodiments, the FFBI film layer 422 may be formed from an oxide, SiN, SiON, SiCN, SiCON, AlOx, ZrOx, HfOx. Although shown with respect to MOS device of GAA type, the novel FFBI can also be applied on MOS device of FinFET and/or Planar type.

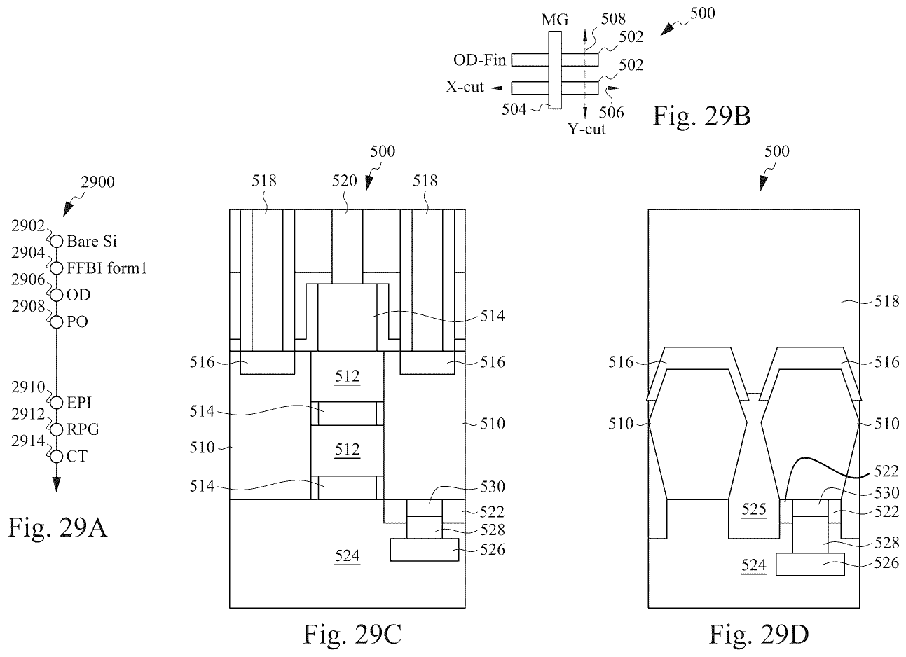

FIG. 29A is a flow diagram depicting an example method 2900 of semiconductor fabrication including fabrication of multi-gate devices, according to various aspects of the present disclosure. FIG. 29A is described in conjunction with FIGS. 29B-29D, which illustrate a semiconductor device 500 or structure at various stages of fabrication in accordance with some embodiments. The method 2900 is merely an example and is not intended to limit the present disclosure beyond what is explicitly recited in the claims. Additional steps may be provided before, during, and after method 2900, and some of the steps described can be moved, replaced, or eliminated for additional embodiments of method 2900. Additional features may be added in the semiconductor device 500 depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 2902, the example method 2900 includes providing a substrate. This block is similar to block 102 of method 100 and reference is made to the corresponding description of block 102 for example description of block 2902.

At block 2904, the example method 2900 includes depositing a dielectric film, referred to herein as a fully flexible bottom isolation (FFBI) film, over the substrate. In this example, the FFBI film is only deposited above the substrate region where a drain feature is to be formed.

At block 2906, the example method 2900 includes forming semiconductor fins (also referred to as fins). This block incorporates operations similar to operations illustrated in block 106 and block 108 of method 100 and reference is made to the corresponding description of block 106 and 108 for example description of block 2906.

At block 2908, the example method 2900 includes forming a sacrificial gate structure on channel regions of the fins, forming gate sidewall spacers on sidewalls of the sacrificial gate structure, and forming an inner spacer layer in sacrificial epitaxial layer recesses. This block incorporates operations similar to operations illustrated in block 110 through block 120 of method 100 and reference is made to the corresponding description of block 110 through block 120 for example description of block 2908.

Method 2900 continues at block 2910, which includes forming source/drain (S/D) features. This block is similar to block 2122 of method 2100 and reference is made to the corresponding description of block 2122 for example description of block 2910.

At block 2912, the example method 2900 includes performing replacement gate operations. This block incorporates operations similar to operations illustrated in block 2124 through block 2132 of method 2100 and reference is made to the corresponding description of block 2124 through block 2132 for example description of block 2912.

At block 2914, the example method 2900 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 2900, and some process steps described above may be replaced or eliminated in accordance with various embodiments of the method 2900.

Referring to the example of FIGS. 29B-29D, in an embodiment of block 2914, an example structure 500 formed during further fabrication is illustrated. FIG. 29B is a top view of the example semiconductor structure 500. Shown are a plurality of fins 502 and a metal gate 504 formed over portions of the fins 502. FIG. 29B also illustrates an X-cut line 506 and a Y-cut line 508.

FIG. 29C illustrates a cross-sectional schematic view of the semiconductor device 500 taken along the X-cut line 506 and FIG. 29D illustrates a cross-sectional schematic view of the semiconductor device 500 taken along the Y-cut line 508. The example semiconductor device 500 includes S/D regions 510, channel regions 512 disposed between the S/D regions 510, metal gate structures 514 disposed around the channel regions 512, salicide regions 516 on top portions of the S/D regions 510, metal drain contacts 518 disposed above the salicide regions 516, a metal gate contact 520 disposed above the metal gate structures 514, an FFBI film layer 522 (e.g., FFBI film layer 207) disposed under a drain region of the S/D regions 510 and a substrate 524 on which the FFBI film layer 522 is formed. An STI feature 525 (silicon trench isolation feature) is shown between the S/D regions 510.

Current MOS gates may encounter MESA leakage current from source to drain through a substrate, may have parasitic capacitance of C_{gd} between the bottom metal gate structure and the drain that can influence the effective capacitance of the device, and the bottom channel region may have worser gate control than other channel regions. The FFBI film layer 522 is a dielectric film formed at the bottom MG 514 and bottom of the S/D regions 510 that isolates S/D regions 510 from the substrate 524. Hence, the FFBI film layer 522 can eliminate MESA leakage and reduce effective capacitance.

In some embodiments, further processing includes providing a backside power rail 526 and a backside VIA for connecting the backside power rail 526 to the drain feature of S/D regions 510. In these embodiments, the FFBI film layer 522 can function as an etch stop layer to prevent damage to the drain region of S/D regions 510 when salicide regions 530 are formed on a bottom region of the drain feature of the S/D regions 510.

In an embodiment, providing a backside power rail 526 and a backside VIA 528 for connecting the backside power rail 526 to the S/D regions 510 may include forming a first recess in the FFBI film layer 522, forming salicide in the first recess, forming a first backside VIA 528 through the first recess that connects to a drain feature 510 through the salicide formed in the first recess, and forming a first backside power rail 526 that connects to the first backside VIA 528.

In various embodiments, the FFBI film layer 522 may not be employed for I/O (input/output) devices or when the spacing between S/D regions are greater than 70 nm (nanometers). In various embodiments, the height of the FFBI film layer 522 may be greater than 5 nm when used with SRAM transistors. In various embodiments, the height of the FFBI film layer 522 may be greater than 10 nm when used with a core device. In various embodiments, an STI-to-FFBI gap 534 may between 0 to approximately 10 nm. In various embodiments, the FFBI film layer 522 may be formed from an oxide, SiN, SiON, SiCN, SiCON, AlOx, ZrOx, HfOx. Although shown with respect to MOS device of GAA type, the novel FFBI can also be applied on MOS device of FinFET and/or Planar type.

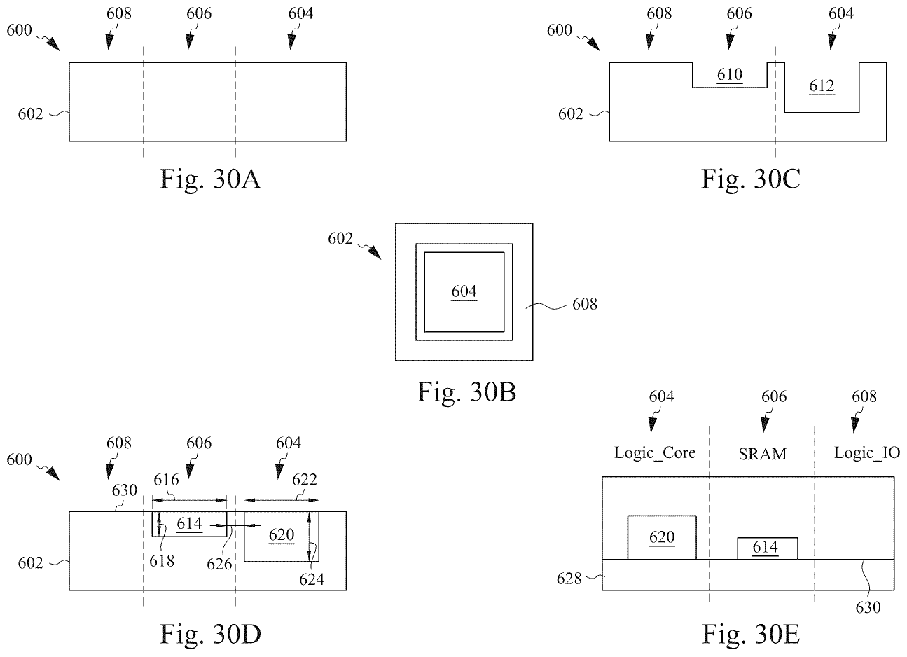

FIG. 30A-FIG. 30E illustrate schematic views of a semiconductor device 600 at various stages of fabricating a FFBI layer in a substrate 602 according to an example method of forming a FFBI layer in a substrate. FIG. 30A depicts a cross-sectional view of the substrate 602 that is provided for forming an FFBI layer in a substrate. The example substrate 602 includes a logic core region 604 wherein a logic core may be fabricated, an SRAM region 606 wherein SRAM cells may be fabricated, and a logic I/O region 608 wherein I/O circuits for the SRAM region 606 or the logic core region 604 may be fabricated.

FIG. 30B depicts a top view of an example region of the substrate 602 that illustrates an example layout of the logic core region 604 with respect to an I/O region 608. In this example, the logic core region 604 is surrounded by the I/O region 608.

FIG. 30C depicts a cross-sectional view of the substrate 602 after etching operations to form trenches for FFBI formation. In the logic core region 604 a first trench 610 is formed. In the SRAM region 606, a second trench 612 is formed. In the I/O region 608, no trench is formed.

After trench formation, the trenches are filled with dielectric material for the FFBI layers and planarized (e.g., using chemical mechanical polishing (CMP)) to form FFBI layers. FIG. 30D depicts a cross-sectional view of the substrate 602 after the trenches are filled with dielectric material and planarized to form FFBI layers. Filling the first trench 610 with dielectric material results in a first FFBI layer 614 having a first width 616 and a first thickness 618. Filling the second trench 612 with the dielectric material results in a second FFBI layer 620 having a second width 622 and a second thickness 624. Also, an FFBI separation space 626 is maintained between various FFBI layers. In various embodiments, the first width 616 is greater than 90 nm, the first thickness 618 is greater than 5 nm, the second width 622 is greater than 90 nm, and the second thickness 624 is greater than 10 nm. In various embodiments, the FFBI separation space 626 is greater than 100 nm.

After FFBI layer formation, a second wafer 628 is bonded to the substrate 602 on a surface 630 of the substrate that is coplanar with an exposed surface of the FFBI layer. The second wafer 628 that is bonded to the substrate 602 may then form the backside of the substrate 602. FIG. 30E depicts a cross-sectional view of the substrate 602 after a second wafer 628 has been bonded to the substrate 602 on the surface 630 and has been flipped over so that further fabrication may be performed on the semiconductor device 600.

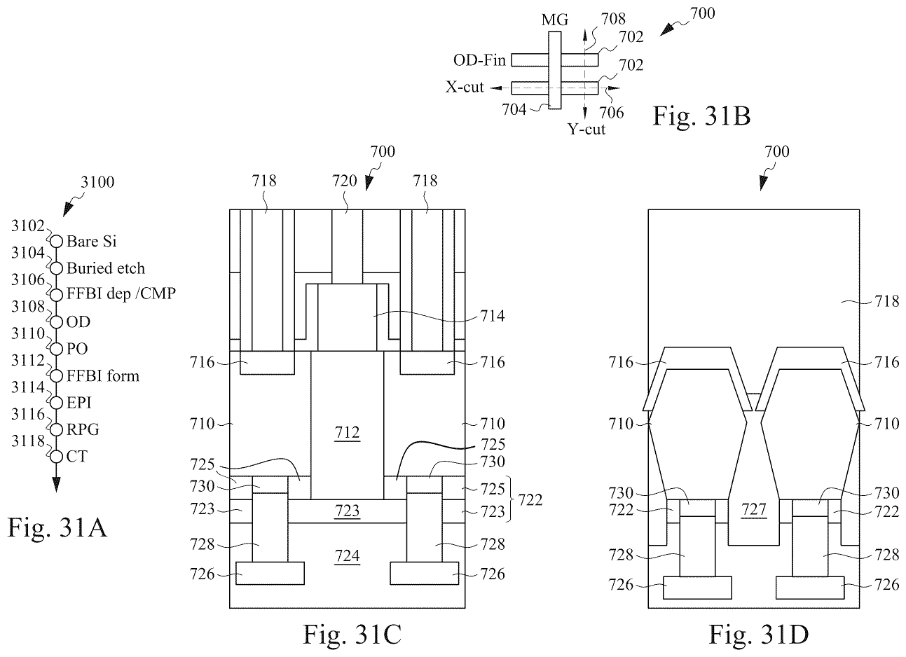

FIG. 31A is a flow diagram depicting an example method 3100 of semiconductor fabrication including fabrication of FinFET devices, according to various aspects of the present disclosure. FIG. 31A is described in conjunction with FIGS. 30A-30E, and 31B-31D, which illustrate a semiconductor device or structure at various stages of fabrication in accordance with some embodiments. The method 3100 is merely an example and is not intended to limit the present disclosure beyond what is explicitly recited in the claims. Additional steps may be provided before, during, and after method 3100, and some of the steps described can be moved, replaced, or eliminated for additional embodiments of method 3100. Additional features may be added in the semiconductor device 700 depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 3102, the example method 3100 includes providing a substrate. Referring to the example of FIG. 30A, in an embodiment of block 3102, a substrate 602 is provided. The example substrate 602 includes a logic core region 604 wherein a logic core may be fabricated, an SRAM region 606 wherein SRAM cells may be fabricated, and a logic I/O region 608 wherein I/O circuits for the SRAM region 606 or the logic core region 604 may be fabricated.

At block 3104, the example method 3100 includes performing a buried etch. Referring to the example of FIG. 30C, in an embodiment of block 3104, the substrate 602 has been etched to form trenches for FFBI formation. In the logic core region 604 a first trench 610 may be formed. In the SRAM region 606, a second trench 612 may be formed. In the I/O region 608, no trench is formed.

At block 3106, the example method 2900 includes forming FFBI layers. In various embodiments, the trenches are filled with dielectric material for the FFBI layers and planarized (e.g., using chemical mechanical polishing (CMP)) to form FFBI layers. Referring to the example of FIG. 30D, in an embodiment of block 3106, the trenches are filled with dielectric material and planarized to form FFBI layers. Filling the first trench 610 with dielectric material results in a first FFBI layer 614 having a first width 616 and a first thickness 618. Filling the second trench 612 with the dielectric material results in a second FFBI layer 620 having a second width 622 and a second thickness 624. Also, an FFBI separation space 626 is maintained between various FFBI layers. In various embodiments, the first width 616 is greater than 90 nm, the first thickness 618 is greater than 5 nm, the second width 622 is greater than 90 nm, and the second thickness 624 is greater than 10 nm. In various embodiments, the FFBI separation space 626 is greater than 100 nm.

At block 3108, the example method 3100 includes forming semiconductor fins (also referred to as fins) for FinFET devices. In various embodiments, forming a fin includes forming an epitaxial layer over the substrate and patterning the epitaxial layer to form semiconductor fins (also referred to as fins). The epitaxial layer may be formed by a molecular beam epitaxy (MBE) process, a metalorganic chemical vapor deposition (MOCVD) process, and/or other suitable epitaxial growth processes. The fins may be fabricated using suitable processes including photolithography and etch processes.

At block 3110, the example method 3100 includes forming a sacrificial gate structure on channel regions of the fins and forming gate sidewall spacers on sidewalls of the sacrificial gate structure. In various embodiments, forming sacrificial gate structures involve forming one or more sacrificial layers/features over the fin and patterning the one or more sacrificial layers/features to form a dummy gate structure on channel regions of the fins.

At block 3112, the example method 3100 Includes forming an additional FFBI film layer over the semiconductor structure. Forming the additional FFBI film layer may include depositing the additional FFBI layer using a CVD process. The additional FFBI film layer may be formed by depositing a material of the same composition as the original FFBI film layer over the original FFBI film layer, the top of the sacrificial gate structure, and the top and sidewalls of the gate sidewall spacers using processes, such as a CVD process, a sub atmospheric CVD (SACVD) process, a flowable CVD process, an ALD process, a PVD process, or other suitable process.

Forming the additional FFBI film layer may also include etching-back the additional FFBI film layer from the top of the sacrificial gate structure and the top and sidewalls of the gate sidewall spacers. In various embodiments, etching-back the additional FFBI film layer may involve an isotropic etching process. In some embodiments, the etching-back process may include a wet etch process, a dry etch process, a multiple-step etch process, and/or a combination thereof.

At block 3114, the example method 3100 includes forming source/drain (S/D) features. In various embodiments, forming the source and drain regions involve forming gate sidewall spacers on sidewalls of the dummy gate structures, recessing the fins in the source drain/regions, and forming gate inner spacers before performing an epitaxial growth process to form the source and drain regions. In various embodiments, forming the source and drain regions also involve forming a CESL layer and an ILD layer around the source drain/regions. In some embodiments, the epitaxial S/D features may include silicon for NFETs and SiGe for PFETs. In some embodiments, the S/D features are formed by an epitaxial growth method using CVD, ALD, or molecular beam epitaxy (MBE).

At block 3116, the example method 3100 includes replacement gate operations. Replacement gate operations may include forming a CESL layer, forming an ILD layer, removing the sacrificial gate structure, and forming metal gate structures.

At block 3118, the example method 3100 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 3100, and some process steps described above may be replaced or eliminated in accordance with various embodiments of the method 3100.

Referring to the example of FIGS. 31B-31D, in an embodiment of block 3118, an example structure 700 formed during further fabrication is illustrated. FIG. 31B is a top view of the example semiconductor structure 700. Shown are a plurality of fins 702 and a metal gate 704 formed over portions of the fins 702. FIG. 31B also illustrates an X-cut line 706 and a Y-cut line 708.

FIG. 31C illustrates a cross-sectional schematic view of the semiconductor device 700 taken along the X-cut line 706 and FIG. 31D illustrates a cross-sectional schematic view of the semiconductor device 700 taken along the Y-cut line 708. The example semiconductor device 700 includes S/D regions 710, channel regions 712 disposed between the S/D regions 710, metal gate structures 714 disposed over the channel regions 712, salicide regions 716 on top portions of the S/D regions 710, metal drain contacts 718 disposed above the salicide regions 716, a metal gate contact 720 disposed above the metal gate structures 714, an FFBI film layer 722 disposed under the S/D regions 710 and channel region 712, and a substrate 724 on which the FFBI film layer 722 is formed. An STI feature 727 (silicon trench isolation feature) is shown between the S/D regions 710. The FFBI film layer 722 comprises an original FFBI film layer 723 and an additional FFBI film layer 725.

Current FinFET gates may encounter MESA leakage current from source to drain through a substrate, may have parasitic capacitance of C_{gd} between the bottom metal gate structure and the drain that can influence the effective capacitance of the device, and the bottom channel region may have worser gate control than other channel regions. The FFBI film layer 722 is a dielectric film formed below the channel region 712 and below the S/D regions 710 that isolates S/D regions 710 from the substrate 724. Hence, the FFBI film layer 722 can eliminate MESA leakage and reduce effective capacitance.

In some embodiments, further processing includes providing a backside power rail 726 and a backside VIA for connecting the backside power rail 726 to the S/D regions 710. In these embodiments, the FFBI film layer 722 can function as an etch stop layer to prevent damage to the S/D regions 710 when salicide regions 730 are formed on bottom regions of the S/D regions 710.

In an embodiment, providing a backside power rail 726 and a backside VIA 728 for connecting the backside power rail 726 to the S/D regions 710 may include forming a first recess in the FFBI film layer 722, forming salicide in the first recess, forming a first backside VIA 728 through the first recess that connects to a drain feature 710 through the salicide formed in the first recess, and forming a first backside power rail 726 that connects to the first backside VIA 728. Providing a backside power rail 726 and a backside VIA 728 for connecting the backside power rail 726 to the S/D regions 710 may also include forming a second recess in the FFBI film layer 722, forming salicide in the second recess, forming a second backside VIA 728 through the second recess that connects to a source feature 710 through the salicide formed in the second recess, and forming a second backside power rail 726 that connects to a second backside VIA 728.

In various embodiments, the FFBI film layer 722 may not be employed for I/O (input/output) devices or when the spacing between S/D regions are greater than 70 nm (nanometers). In various embodiments, the thickness of the FFBI film layer 722 may be greater than 5 nm when used with SRAM transistors. In various embodiments, the thickness of the FFBI film layer 722 may be greater than 10 nm when used with a core device. In various embodiments, the FFBI film layer 722 may be formed from an oxide, SiN, SiON, SiCN, SiCON, AlOx, ZrOx, HfOx.

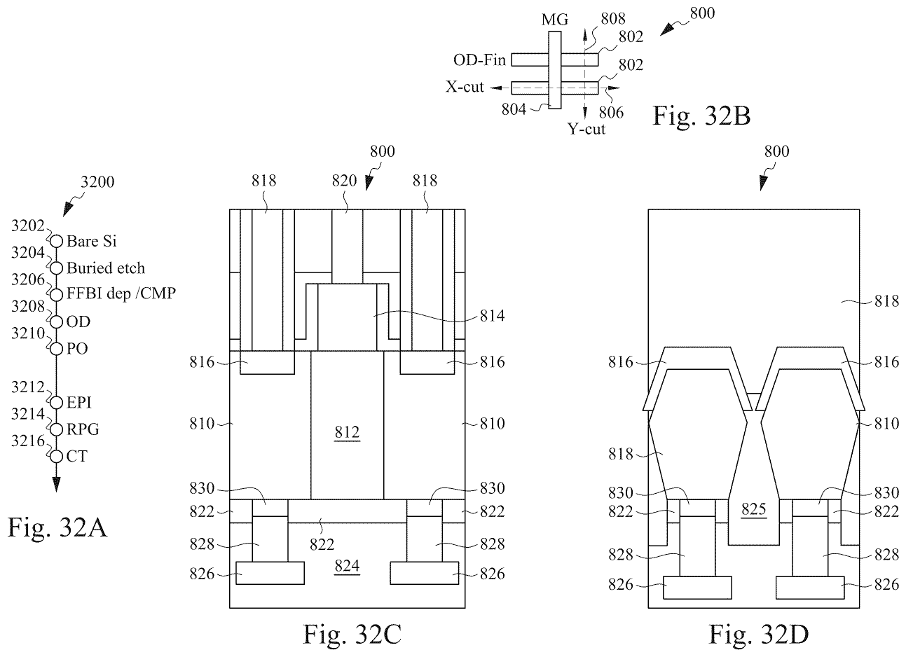

FIG. 32A is a flow diagram depicting an example method 3200 of semiconductor fabrication including fabrication of FinFET devices, according to various aspects of the present disclosure. FIG. 32A is described in conjunction with FIGS. 30A-30E, and 32B-32D, which illustrate a semiconductor device or structure at various stages of fabrication in accordance with some embodiments. The method 3200 is merely an example and is not intended to limit the present disclosure beyond what is explicitly recited in the claims. Additional steps may be provided before, during, and after method 3200, and some of the steps described can be moved, replaced, or eliminated for additional embodiments of method 3200. Additional features may be added in the semiconductor device 800 depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 3202, the example method 3200 includes providing a substrate. Referring to the example of FIG. 30A, in an embodiment of block 3202, a substrate 602 is provided. The example substrate 602 includes a logic core region 604 wherein a logic core may be fabricated, an SRAM region 606 wherein SRAM cells may be fabricated, and a logic I/O region 608 wherein I/O circuits for the SRAM region 606 or the logic core region 604 may be fabricated.

At block 3204, the example method 3200 includes performing a buried etch. Referring to the example of FIG. 30C, in an embodiment of block 3204, the substrate 602 has been etched to form trenches for FFBI formation. In the logic core region 604 a first trench 610 may be formed. In the SRAM region 606, a second trench 612 may be formed. In the I/O region 608, no trench is formed.

At block 3206, the example method 3200 includes forming FFBI layers. In various embodiments, the trenches are filled with dielectric material for the FFBI layers and planarized (e.g., using chemical mechanical polishing (CMP)) to form FFBI layers. Referring to the example of FIG. 30D, in an embodiment of block 3206, the trenches are filled with dielectric material and planarized to form FFBI layers. Filling the first trench 610 with dielectric material results in a first FFBI layer 614 having a first width 616 and a first thickness 618. Filling the second trench 612 with the dielectric material results in a second FFBI layer 620 having a second width 622 and a second thickness 624. Also, an FFBI separation space 626 is maintained between various FFBI layers. In various embodiments, the first width 616 is greater than 90 nm, the first thickness 618 is greater than 5 nm, the second width 622 is greater than 90 nm, and the second thickness 624 is greater than 10 nm. In various embodiments, the FFBI separation space 626 is greater than 100 nm.

At block 3208, the example method 3200 includes forming semiconductor fins (also referred to as fins) for FinFET devices.

At block 3210, the example method 3200 includes forming a sacrificial gate structure on channel regions of the fins and forming gate sidewall spacers on sidewalls of the sacrificial gate structure.

At block 3212, the example method 3200 includes forming source/drain (S/D) features. In some embodiments, the epitaxial S/D features may include silicon for NFETs and SiGe for PFETs. In some embodiments, the S/D features are formed by an epitaxial growth method using CVD, ALD, or molecular beam epitaxy (MBE).

At block 3214, the example method 3200 includes replacement gate operations. Replacement gate operations may include forming a CESL layer, forming an ILD layer, removing the sacrificial gate structure, and forming metal gate structures.

At block 3216, the example method 3200 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 3200, and some process steps described above may be replaced or eliminated in accordance with various embodiments of the method 3200.

Referring to the example of FIGS. 32B-32D, in an embodiment of block 3216, an example structure 800 formed during further fabrication is illustrated. FIG. 32B is a top view of the example semiconductor structure 800. Shown are a plurality of fins 802 and a metal gate 804 formed over portions of the fins 802. FIG. 32B also illustrates an X-cut line 806 and a Y-cut line 808.

FIG. 32C illustrates a cross-sectional schematic view of the semiconductor device 800 taken along the X-cut line 806 and FIG. 32D illustrates a cross-sectional schematic view of the semiconductor device 800 taken along the Y-cut line 808. The example semiconductor device 800 includes S/D regions 810, channel regions 812 disposed between the S/D regions 810, metal gate structures 814 disposed over the channel regions 812, salicide regions 816 on top portions of the S/D regions 810, metal drain contacts 818 disposed above the salicide regions 816, a metal gate contact 820 disposed above the metal gate structures 814, an FFBI film layer 822 disposed under the S/D regions 810 and channel region 812, and a substrate 824 on which the FFBI film layer 822 is formed. An STI feature 825 (silicon trench isolation feature) is shown between the S/D regions 810.

Current FinFET gates may encounter MESA leakage current from source to drain through a substrate, may have parasitic capacitance of C_{gd} between the bottom metal gate structure and the drain that can influence the effective capacitance of the device, and the bottom channel region may have worser gate control than other channel regions. The FFBI film layer 822 is a dielectric film formed below the channel region 812 and below the S/D regions 810 that isolates S/D regions 810 from the substrate 824. Hence, the FFBI film layer 822 can eliminate MESA leakage and reduce effective capacitance.

In some embodiments, further processing includes providing a backside power rail 826 and a backside VIA for connecting the backside power rail 826 to the S/D regions 810. In these embodiments, the FFBI film layer 822 can function as an etch stop layer to prevent damage to the S/D regions 810 when salicide regions 830 are formed on bottom regions of the S/D regions 810.

In an embodiment, providing a backside power rail 826 and a backside VIA 828 for connecting the backside power rail 826 to the S/D regions 810 may include forming a first recess in the FFBI film layer 822, forming salicide in the first recess, forming a first backside VIA 828 through the first recess that connects to a drain feature 810 through the salicide formed in the first recess, and forming a first backside power rail 826 that connects to the first backside VIA 828. Providing a backside power rail 826 and a backside VIA 828 for connecting the backside power rail 826 to the S/D regions 810 may also include forming a second recess in the FFBI film layer 822, forming salicide in the second recess, forming a second backside VIA 828 through the second recess that connects to a source feature 810 through the salicide formed in the second recess, and forming a second backside power rail 826 that connects to a second backside VIA 828.

In various embodiments, the FFBI film layer 822 may not be employed for I/O (input/output) devices or when the spacing between S/D regions are greater than 70 nm (nanometers). In various embodiments, the thickness of the FFBI film layer 822 may be greater than 5 nm when used with SRAM transistors. In various embodiments, the thickness of the FFBI film layer 822 may be greater than 10 nm when used with a core device. In various embodiments, the FFBI film layer 822 may be formed from an oxide, SiN, SiON, SiCN, SiCON, AlOx, ZrOx, HfOx.

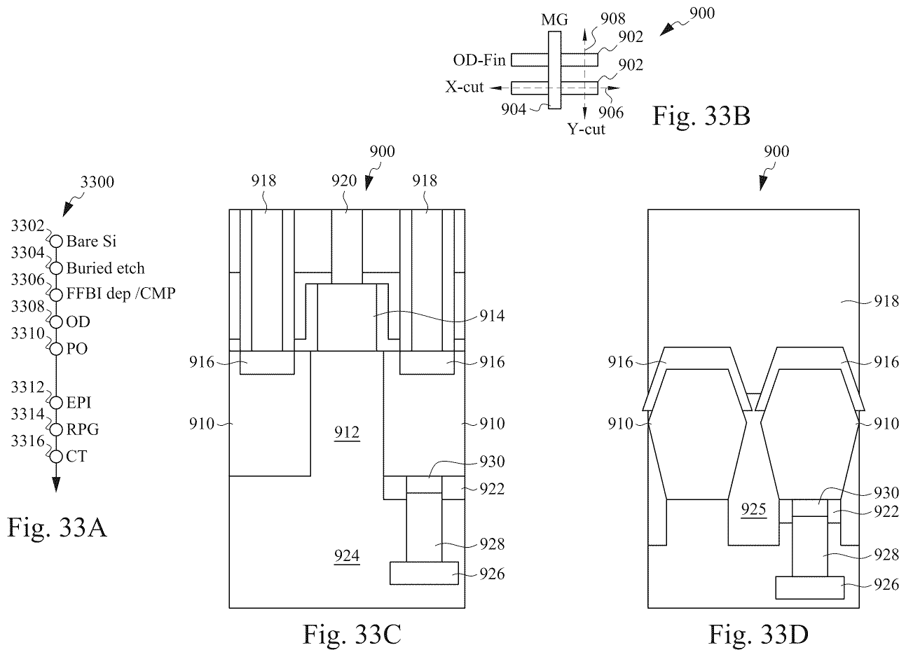

FIG. 33A is a flow diagram depicting an example method 3300 of semiconductor fabrication including fabrication of FinFET devices, according to various aspects of the present disclosure. FIG. 33A is described in conjunction with FIGS. 30A-30E, and 33B-33D, which illustrate a semiconductor device or structure at various stages of fabrication in accordance with some embodiments. The method 3300 is merely an example and is not intended to limit the present disclosure beyond what is explicitly recited in the claims. Additional steps may be provided before, during, and after method 3300, and some of the steps described can be moved, replaced, or eliminated for additional embodiments of method 3300. Additional features may be added in the semiconductor device 900 depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 3302, the example method 3300 includes providing a substrate. Referring to the example of FIG. 30A, in an embodiment of block 3302, a substrate 602 is provided. The example substrate 602 includes a logic core region 604 wherein a logic core may be fabricated, an SRAM region 606 wherein SRAM cells may be fabricated, and a logic I/O region 608 wherein I/O circuits for the SRAM region 606 or the logic core region 604 may be fabricated.

At block 3304, the example method 3300 includes performing a buried etch. Referring to the example of FIG. 30C, in an embodiment of block 3304, the substrate 602 has been etched to form trenches for FFBI formation. In the logic core region 604 a first trench 610 may be formed. In the SRAM region 606, a second trench 612 may be formed. In the I/O region 608, no trench is formed. In this example, a trench is formed in the substrate region where a drain feature is to be formed, but not where a source feature or a channel region is to be formed.

At block 3306, the example method 3300 includes forming FFBI layers. In various embodiments, the trenches are filled with dielectric material for the FFBI layers and planarized (e.g., using chemical mechanical polishing (CMP)) to form FFBI layers. Referring to the example of FIG. 30D, in an embodiment of block 3306, the trenches are filled with dielectric material and planarized to form FFBI layers. Filling the first trench 610 with dielectric material results in a first FFBI layer 614 having a first width 616 and a first thickness 618. Filling the second trench 612 with the dielectric material results in a second FFBI layer 620 having a second width 622 and a second thickness 624. Also, an FFBI separation space 626 is maintained between various FFBI layers. In various embodiments, the first width 616 is greater than 90 nm, the first thickness 618 is greater than 5 nm, the second width 622 is greater than 90 nm, and the second thickness 624 is greater than 10 nm. In various embodiments, the FFBI separation space 626 is greater than 100 nm.

At block 3308, the example method 3300 includes forming semiconductor fins (also referred to as fins) for FinFET devices.

At block 3310, the example method 3300 includes forming a sacrificial gate structure on channel regions of the fins and forming gate sidewall spacers on sidewalls of the sacrificial gate structure.

At block 3312, the example method 3300 includes forming source/drain (S/D) features. In some embodiments, the epitaxial S/D features may include silicon for NFETs and SiGe for PFETs. In some embodiments, the S/D features are formed by an epitaxial growth method using CVD, ALD, or molecular beam epitaxy (MBE).

At block 3314, the example method 3300 includes replacement gate operations. Replacement gate operations may include forming a CESL layer, forming an ILD layer, removing the sacrificial gate structure, and forming metal gate structures.

At block 3316, the example method 3300 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 3300, and some process steps described above may be replaced or eliminated in accordance with various embodiments of the method 3300.

Referring to the example of FIGS. 33B-33D, in an embodiment of block 3316, an example structure 900 formed during further fabrication is illustrated. FIG. 33B is a top view of the example semiconductor structure 900. Shown are a plurality of fins 902 and a metal gate 904 formed over portions of the fins 902. FIG. 33B also illustrates an X-cut line 906 and a Y-cut line 908.

FIG. 33C illustrates a cross-sectional schematic view of the semiconductor device 900 taken along the X-cut line 906 and FIG. 33D illustrates a cross-sectional schematic view of the semiconductor device 900 taken along the Y-cut line 908. The example semiconductor device 900 includes S/D regions 910, channel regions 912 disposed between the S/D regions 910, metal gate structures 914 disposed over the channel regions 912, salicide regions 916 on top portions of the S/D regions 910, metal drain contacts 918 disposed above the salicide regions 916, a metal gate contact 920 disposed above the metal gate structures 914, an FFBI film layer 922 disposed under the S/D regions 910 and channel region 912, and a substrate 924 on which the FFBI film layer 922 is formed. An STI feature 925 (silicon trench isolation feature) is shown between the S/D regions 910.

Current FinFET gates may encounter MESA leakage current from source to drain through a substrate, may have parasitic capacitance of C_{gd} between the bottom metal gate structure and the drain that can influence the effective capacitance of the device, and the bottom channel region may have worser gate control than other channel regions. The FFBI film layer 922 is a dielectric film formed below the channel region 912 and below the S/D regions 910 that isolates S/D regions 910 from the substrate 924. Hence, the FFBI film layer 922 can eliminate MESA leakage and reduce effective capacitance.

In some embodiments, further processing includes providing a backside power rail 926 and a backside VIA for connecting the backside power rail 926 to the S/D regions 910. In these embodiments, the FFBI film layer 922 can function as an etch stop layer to prevent damage to the S/D regions 910 when salicide regions 930 are formed on bottom regions of the S/D regions 910.

In an embodiment, providing a backside power rail 926 and a backside VIA 928 for connecting the backside power rail 926 to the S/D regions 910 may include forming a first recess in the FFBI film layer 922, forming salicide in the first recess, forming a first backside VIA 928 through the first recess that connects to a drain feature 910 through the salicide formed in the first recess, and forming a first backside power rail 926 that connects to the first backside VIA 928. Providing a backside power rail 926 and a backside VIA 928 for connecting the backside power rail 926 to the S/D regions 910 may also include forming a second recess in the FFBI film layer 922, forming salicide in the second recess, forming a second backside VIA 928 through the second recess that connects to a source feature 910 through the salicide formed in the second recess, and forming a second backside power rail 926 that connects to a second backside VIA 928.

In various embodiments, the FFBI film layer 922 may not be employed for I/O (input/output) devices or when the spacing between S/D regions are greater than 70 nm (nanometers). In various embodiments, the thickness of the FFBI film layer 922 may be greater than 5 nm when used with SRAM transistors. In various embodiments, the thickness of the FFBI film layer 922 may be greater than 10 nm when used with a core device. In various embodiments, the FFBI film layer 922 may be formed from an oxide, SiN, SiON, SiCN, SiCON, AlOx, ZrOx, HfOx.

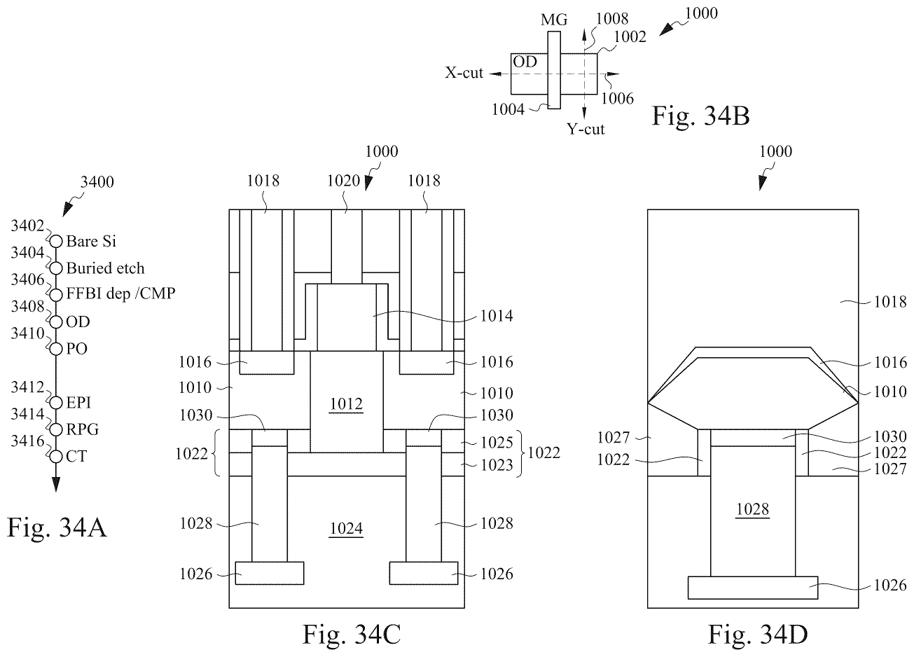

FIG. 34A is a flow diagram depicting an example method 3400 of semiconductor fabrication including fabrication of planar MOS devices, according to various aspects of the present disclosure. FIG. 34A is described in conjunction with FIGS. 30A-30E, and 34B-34D, which illustrate a semiconductor device or structure at various stages of fabrication in accordance with some embodiments. The method 3400 is merely an example and is not intended to limit the present disclosure beyond what is explicitly recited in the claims. Additional steps may be provided before, during, and after method 3400, and some of the steps described can be moved, replaced, or eliminated for additional embodiments of method 3400. Additional features may be added in the semiconductor device 1000 depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 3402, the example method 3400 includes providing a substrate. Referring to the example of FIG. 30A, in an embodiment of block 3402, a substrate 602 is provided. The example substrate 602 includes a logic core region 604 wherein a logic core may be fabricated, an SRAM region 606 wherein SRAM cells may be fabricated, and a logic I/O region 608 wherein I/O circuits for the SRAM region 606 or the logic core region 604 may be fabricated.

At block 3404, the example method 3400 includes performing a buried etch. Referring to the example of FIG. 30C, in an embodiment of block 3404, the substrate 602 has been etched to form trenches for FFBI formation. In the logic core region 604 a first trench 610 may be formed. In the SRAM region 606, a second trench 612 may be formed. In the I/O region 608, no trench is formed.

At block 3406, the example method 2900 includes forming original FFBI layers. In various embodiments, the trenches are filled with dielectric material for the FFBI layers and planarized (e.g., using chemical mechanical polishing (CMP)) to form FFBI layers. Referring to the example of FIG. 30D, in an embodiment of block 3406, the trenches are filled with dielectric material and planarized to form FFBI layers. Filling the first trench 610 with dielectric material results in a first FFBI layer 614 having a first width 616 and a first thickness 618. Filling the second trench 612 with the dielectric material results in a second FFBI layer 620 having a second width 622 and a second thickness 624. Also, an FFBI separation space 626 is maintained between various FFBI layers. In various embodiments, the first width 616 is greater than 90 nm, the first thickness 618 is greater than 5 nm, the second width 622 is greater than 90 nm, and the second thickness 624 is greater than 10 nm. In various embodiments, the FFBI separation space 626 is greater than 100 nm. In various embodiments, an additional FFBI layer is formed above the original FFBI layer in the source/drain region of the planar device.

At block 3408, the example method 3400 includes forming an active region for a planar device. At block 3410, the example method 3400 includes forming a sacrificial gate structure on a channel region of the planar device and forming gate sidewall spacers on sidewalls of the sacrificial gate structure. At block 3412, the example method 3400 Includes forming source/drain (S/D) features. At block 3414, the example method 3400 includes replacement gate operations. Replacement gate operations may include forming a CESL layer, forming an ILD layer, removing the sacrificial gate structure, and forming metal gate structures.

At block 3416, the example method 3400 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 3400, and some process steps described above may be replaced or eliminated in accordance with various embodiments of the method 3400.

Referring to the example of FIGS. 34B-34D, in an embodiment of block 3416, an example structure 1000 formed during further fabrication is illustrated. FIG. 34B is a top view of the example semiconductor structure 1000. Shown are an active region 1002 and a metal gate 1004 formed over portions of the active region 1002. FIG. 34B also illustrates an X-cut line 1006 and a Y-cut line 1008.

FIG. 34C illustrates a cross-sectional schematic view of the semiconductor device 1000 taken along the X-cut line 1006 and FIG. 34D illustrates a cross-sectional schematic view of the semiconductor device 1000 taken along the Y-cut line 1008. The example semiconductor device 1000 includes S/D regions 1010, channel regions 1012 disposed between the S/D regions 1010, metal gate structures 1014 disposed over the channel regions 1012, salicide regions 1016 on top portions of the S/D regions 1010, metal drain contacts 1018 disposed above the salicide regions 1016, a metal gate contact 1020 disposed above the metal gate structures 1014, an FFBI film layer 1022 disposed under the S/D regions 1010 and channel region 1012, and a substrate 1024 on which the FFBI film layer 1022 is formed. An STI feature 1027 (silicon trench isolation feature) is shown between the S/D regions 1010. The FFBI film layer 1022 comprises an original FFBI film layer 1023 and an additional FFBI film layer 1025.

Current planar MOS gates may encounter MESA leakage current from source to drain through a substrate. The FFBI film layer 1022 is a dielectric film formed below the channel region 1012 and below the S/D regions 1010 that isolates S/D regions 1010 from the substrate 1024. Hence, the FFBI film layer 1022 can eliminate MESA leakage and reduce effective capacitance.

In some embodiments, further processing includes providing a backside power rail 1026 and a backside VIA for connecting the backside power rail 1026 to the S/D regions 1010. In these embodiments, the FFBI film layer 1022 can function as an etch stop layer to prevent damage to the S/D regions 1010 when salicide regions 1030 are formed on bottom regions of the S/D regions 1010.

In an embodiment, providing a backside power rail 1026 and a backside VIA 1028 for connecting the backside power rail 1026 to the S/D regions 1010 may include forming a first recess in the FFBI film layer 1022, forming salicide in the first recess, forming a first backside VIA 1028 through the first recess that connects to a drain feature 1010 through the salicide formed in the first recess, and forming a first backside power rail 1026 that connects to the first backside VIA 1028. Providing a backside power rail 1026 and a backside VIA 1028 for connecting the backside power rail 1026 to the S/D regions 1010 may also include forming a second recess in the FFBI film layer 1022, forming salicide in the second recess, forming a second backside VIA 1028 through the second recess that connects to a source feature 1010 through the salicide formed in the second recess, and forming a second backside power rail 1026 that connects to a second backside VIA 1028.

In various embodiments, the FFBI film layer 1022 may not be employed for I/O (input/output) devices or when the spacing between S/D regions are greater than 70 nm (nanometers). In various embodiments, the thickness of the FFBI film layer 1022 may be greater than 5 nm when used with SRAM transistors. In various embodiments, the thickness of the FFBI film layer 1022 may be greater than 10 nm when used with a core device. In various embodiments, the FFBI film layer 1022 may be formed from an oxide, SiN, SiON, SiCN, SiCON, AlOx, ZrOx, HfOx.

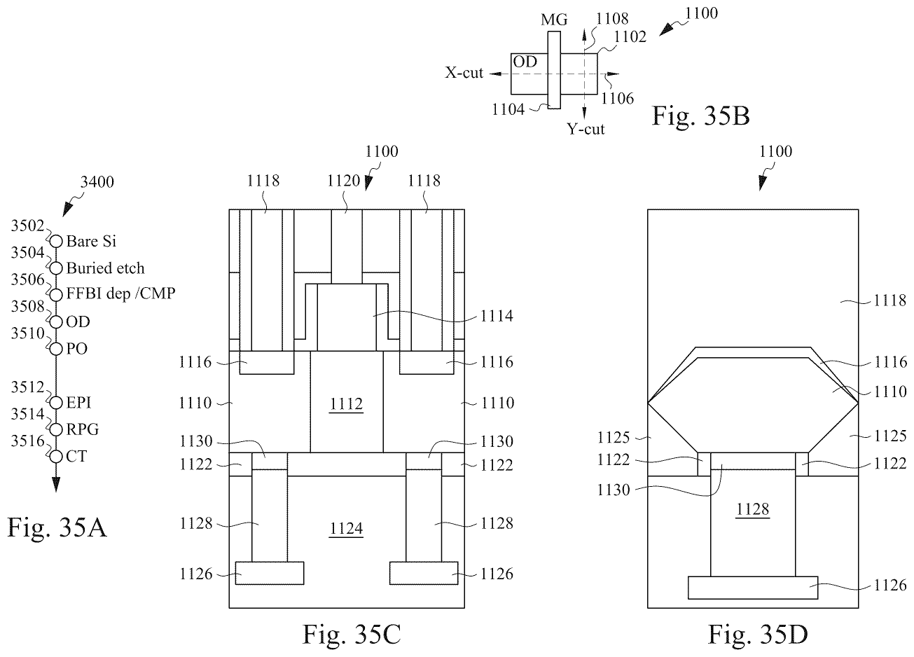

FIG. 35A is a flow diagram depicting an example method 3500 of semiconductor fabrication including fabrication of planar MOS devices, according to various aspects of the present disclosure. FIG. 35A is described in conjunction with FIGS. 30A-30E, and 35B-35D, which illustrate a semiconductor device or structure at various stages of fabrication in accordance with some embodiments. The method 3500 is merely an example and is not intended to limit the present disclosure beyond what is explicitly recited in the claims. Additional steps may be provided before, during, and after method 3500, and some of the steps described can be moved, replaced, or eliminated for additional embodiments of method 3500. Additional features may be added in the semiconductor device 1100 depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 3502, the example method 3500 includes providing a substrate. Referring to the example of FIG. 30A, in an embodiment of block 3502, a substrate 602 is provided. The example substrate 602 includes a logic core region 604 wherein a logic core may be fabricated, an SRAM region 606 wherein SRAM cells may be fabricated, and a logic I/O region 608 wherein I/O circuits for the SRAM region 606 or the logic core region 604 may be fabricated.

At block 3504, the example method 3500 includes performing a buried etch. Referring to the example of FIG. 30C, in an embodiment of block 3504, the substrate 602 has been etched to form trenches for FFBI formation. In the logic core region 604, a first trench 610 may be formed. In the SRAM region 606, a second trench 612 may be formed. In the I/O region 608, no trench is formed.

At block 3506, the example method 2900 includes forming FFBI layers. In various embodiments, the trenches are filled with dielectric material for the FFBI layers and planarized (e.g., using chemical mechanical polishing (CMP)) to form FFBI layers. Referring to the example of FIG. 30D, in an embodiment of block 3506, the trenches are filled with dielectric material and planarized to form FFBI layers. Filling the first trench 610 with dielectric material results in a first FFBI layer 614 having a first width 616 and a first thickness 618. Filling the second trench 612 with the dielectric material results in a second FFBI layer 620 having a second width 622 and a second thickness 624. Also, an FFBI separation space 626 is maintained between various FFBI layers. In various embodiments, the first width 616 is greater than 90 nm, the first thickness 618 is greater than 5 nm, the second width 622 is greater than 90 nm, and the second thickness 624 is greater than 10 nm. In various embodiments, the FFBI separation space 626 is greater than 100 nm.

At block 3508, the example method 3500 includes forming an active region for a planar device. At block 3510, the example method 3500 includes forming a sacrificial gate structure on a channel region of the planar device and forming gate sidewall spacers on sidewalls of the sacrificial gate structure. At block 3512, the example method 3500 Includes forming source/drain (S/D) features. At block 3514, the example method 3500 includes replacement gate operations. Replacement gate operations may include forming a CESL layer, forming an ILD layer, removing the sacrificial gate structure, and forming metal gate structures.

At block 3516, the example method 3500 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 3500, and some process steps described above may be replaced or eliminated in accordance with various embodiments of the method 3500.

Referring to the example of FIGS. 35B-35D, in an embodiment of block 3516, an example structure 1100 formed during further fabrication is illustrated. FIG. 35B is a top view of the example semiconductor structure 1100. Shown are an active region 1102 and a metal gate 1104 formed over portions of the active region 1102. FIG. 35B also illustrates an X-cut line 1106 and a Y-cut line 1108.

FIG. 35C illustrates a cross-sectional schematic view of the semiconductor device 1100 taken along the X-cut line 1106 and FIG. 35D illustrates a cross-sectional schematic view of the semiconductor device 1100 taken along the Y-cut line 1108. The example semiconductor device 1100 includes S/D regions 1110, channel regions 1112 disposed between the S/D regions 1110, metal gate structures 1114 disposed over the channel regions 1112, salicide regions 1116 on top portions of the S/D regions 1110, metal drain contacts 1118 disposed above the salicide regions 1116, a metal gate contact 1120 disposed above the metal gate structures 1114, an FFBI film layer 1122 disposed under the S/D regions 1110 and channel region 1112, and a substrate 1124 on which the FFBI film layer 1122 is formed. An STI feature 1125 (silicon trench isolation feature) is shown between the S/D regions 1110.

Current planar MOS gates may encounter MESA leakage current from source to drain through a substrate. The FFBI film layer 1122 is a dielectric film formed below the channel region 1112 and below the S/D regions 1110 that isolates S/D regions 1110 from the substrate 1124. Hence, the FFBI film layer 1122 can eliminate MESA leakage and reduce effective capacitance.

In some embodiments, further processing includes providing a backside power rail 1126 and a backside VIA for connecting the backside power rail 1126 to the S/D regions 1110. In these embodiments, the FFBI film layer 1122 can function as an etch stop layer to prevent damage to the S/D regions 1110 when salicide regions 1130 are formed on bottom regions of the S/D regions 1110.

In an embodiment, providing a backside power rail 1126 and a backside VIA 1128 for connecting the backside power rail 1126 to the S/D regions 1110 may include forming a first recess in the FFBI film layer 1122, forming salicide in the first recess, forming a first backside VIA 1128 through the first recess that connects to a drain feature 1110 through the salicide formed in the first recess, and forming a first backside power rail 1126 that connects to the first backside VIA 1128. Providing a backside power rail 1126 and a backside VIA 1128 for connecting the backside power rail 1126 to the S/D regions 1110 may also include forming a second recess in the FFBI film layer 1122, forming salicide in the second recess, forming a second backside VIA 1128 through the second recess that connects to a source feature 1110 through the salicide formed in the second recess, and forming a second backside power rail 1126 that connects to a second backside VIA 1128.

In various embodiments, the FFBI film layer 1122 may not be employed for I/O (input/output) devices or when the spacing between S/D regions are greater than 70 nm (nanometers). In various embodiments, the thickness of the FFBI film layer 1122 may be greater than 5 nm when used with SRAM transistors. In various embodiments, the thickness of the FFBI film layer 1122 may be greater than 10 nm when used with a core device. In various embodiments, the FFBI film layer 1122 may be formed from an oxide, SiN, SiON, SiCN, SiCON, AlOx, ZrOx, HfOx.

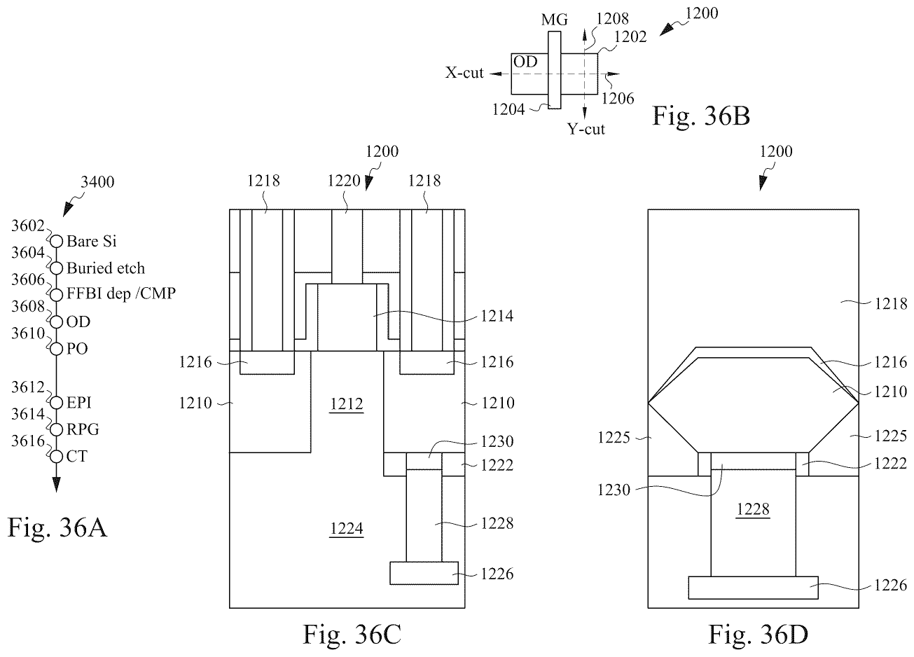

FIG. 36A is a flow diagram depicting an example method 3600 of semiconductor fabrication including fabrication of planar MOS devices, according to various aspects of the present disclosure. FIG. 36A is described in conjunction with FIGS. 30A-30E, and 36B-36D, which illustrate a semiconductor device or structure at various stages of fabrication in accordance with some embodiments. The method 3600 is merely an example and is not intended to limit the present disclosure beyond what is explicitly recited in the claims. Additional steps may be provided before, during, and after method 3600, and some of the steps described can be moved, replaced, or eliminated for additional embodiments of method 3600. Additional features may be added in the semiconductor device 1200 depicted in the figures, and some of the features described below can be replaced, modified, or eliminated in other embodiments. In some figures, some reference numbers of components or features illustrated therein may be omitted to avoid obscuring other components or features; this is for ease of depicting the figures.

At block 3602, the example method 3600 includes providing a substrate. Referring to the example of FIG. 30A, in an embodiment of block 3602, a substrate 602 is provided. The example substrate 602 includes a logic core region 604 wherein a logic core may be fabricated, an SRAM region 606 wherein SRAM cells may be fabricated, and a logic I/O region 608 wherein I/O circuits for the SRAM region 606 or the logic core region 604 may be fabricated.

At block 3604, the example method 3600 includes performing a buried etch. Referring to the example of FIG. 30C, in an embodiment of block 3604, the substrate 602 has been etched to form trenches for FFBI formation. In the logic core region 604 a first trench 610 may be formed. In the SRAM region 606, a second trench 612 may be formed. In the I/O region 608, no trench is formed. In this example, a trench is formed in the substrate region where a drain feature is to be formed, but not where a source feature or a channel region is to be formed.

At block 3606, the example method 3600 includes forming original FFBI layers. In various embodiments, the trenches are filled with dielectric material for the FFBI layers and planarized (e.g., using chemical mechanical polishing (CMP)) to form FFBI layers. Referring to the example of FIG. 30D, in an embodiment of block 3606, the trenches are filled with dielectric material and planarized to form FFBI layers. Filling the first trench 610 with dielectric material results in a first FFBI layer 614 having a first width 616 and a first thickness 618. Filling the second trench 612 with the dielectric material results in a second FFBI layer 620 having a second width 622 and a second thickness 624. Also, an FFBI separation space 626 is maintained between various FFBI layers. In various embodiments, the first width 616 is greater than 90 nm, the first thickness 618 is greater than 5 nm, the second width 622 is greater than 90 nm, and the second thickness 624 is greater than 10 nm. In various embodiments, the FFBI separation space 626 is greater than 100 nm.

At block 3608, the example method 3600 includes forming an active region for a planar device. At block 3610, the example method 3600 includes forming a sacrificial gate structure on a channel region of the planar device and forming gate sidewall spacers on sidewalls of the sacrificial gate structure. At block 3612, the example method 3600 Includes forming source/drain (S/D) features. At block 3614, the example method 3600 includes replacement gate operations. Replacement gate operations may include forming a CESL layer, forming an ILD layer, removing the sacrificial gate structure, and forming metal gate structures.

At block 3616, the example method 3600 includes performing further fabrication. A semiconductor device may undergo further processing to form various features and regions known in the art. For example, subsequent processing may include filling the opening over the source/drain regions with ILD1 material to fill in the ILD1 layer and forming one or more intermetal dielectric (IMD) layers over the ILD1 layer. Each IMD layer may include an etch stop layer (ESL) above the underlying layer and an ILD layer above the ESL. The ESL may be deposited using one or more low temperature deposition processes such as chemical vapor deposition, physical vapor deposition, or atomic layer deposition. Subsequent processing may also include forming contact openings, contact metal, as well as various contacts/vias/lines and multilayer interconnect features (e.g., metal layers and interlayer dielectrics) on the substrate, configured to connect the various features to form a functional circuit that may include one or more multi-gate devices. In furtherance of the example, a multilayer interconnection may include vertical interconnects, such as vias or contacts, and horizontal interconnects, such as metal lines. The various interconnection features may employ various conductive materials including copper, tungsten, and/or silicide. In one example, a damascene and/or dual damascene process is used to form a copper related multilayer interconnection structure. Moreover, additional process steps may be implemented before, during, and after the method 3600, and some process steps described above may be replaced or eliminated in accordance with various embodiments of the method 3600.

Referring to the example of FIGS. 36B-36D, in an embodiment of block 3616, an example structure 1200 formed during further fabrication is illustrated. FIG. 36B is a top view of the example semiconductor structure 1200. Shown are an active region 1202 and a metal gate 1204 formed over portions of the active region 1202. FIG. 36B also illustrates an X-cut line 1206 and a Y-cut line 1208.

FIG. 36C illustrates a cross-sectional schematic view of the semiconductor device 1200 taken along the X-cut line 1206 and FIG. 36D illustrates a cross-sectional schematic view of the semiconductor device 1200 taken along the Y-cut line 1208. The example semiconductor device 1200 includes S/D regions 1210, channel regions 1212 disposed between the S/D regions 1210, metal gate structures 1214 disposed over the channel regions 1212, salicide regions 1216 on top portions of the S/D regions 1210, metal drain contacts 1218 disposed above the salicide regions 1216, a metal gate contact 1220 disposed above the metal gate structures 1214, an FFBI film layer 1222 disposed under the S/D regions 1210 and channel region 1212, and a substrate 1224 on which the FFBI film layer 1222 is formed. An STI feature 1225 (silicon trench isolation feature) is shown between the S/D regions 1210.

Current planar MOS gates may encounter MESA leakage current from source to drain through a substrate. The FFBI film layer 1222 is a dielectric film formed below the channel region 1212 and below the S/D regions 1210 that isolates S/D regions 1210 from the substrate 1224. Hence, the FFBI film layer 1222 can eliminate MESA leakage and reduce effective capacitance.

In some embodiments, further processing includes providing a backside power rail 1226 and a backside VIA for connecting the backside power rail 1226 to the S/D regions 1210. In these embodiments, the FFBI film layer 1222 can function as an etch stop layer to prevent damage to the S/D regions 1210 when salicide regions 1230 are formed on bottom regions of the S/D regions 1210.

In an embodiment, providing a backside power rail 1226 and a backside VIA 1228 for connecting the backside power rail 1226 to the S/D regions 1210 may include forming a first recess in the FFBI film layer 1222, forming salicide in the first recess, forming a first backside VIA 1228 through the first recess that connects to a drain feature 1210 through the salicide formed in the first recess, and forming a first backside power rail 1226 that connects to the first backside VIA 1228.

In various embodiments, the FFBI film layer 1222 may not be employed for I/O (input/output) devices or when the spacing between S/D regions are greater than 70 nm (nanometers). In various embodiments, the thickness of the FFBI film layer 1222 may be greater than 5 nm when used with SRAM transistors. In various embodiments, the thickness of the FFBI film layer 1222 may be greater than 10 nm when used with a core device. In various embodiments, the FFBI film layer 1222 may be formed from an oxide, SiN, SiON, SiCN, SiCON, AlOx, ZrOx, HfOx.

In some aspects, the techniques described herein relate to a semiconductor structure, including: a dielectric layer disposed on a substrate below a drain feature of a MOS device; wherein the dielectric layer isolates the drain feature from the substrate.

In some aspects, the techniques described herein relate to a semiconductor structure, further including a backside power rail and a backside VIA that connect to the drain feature through salicide formed in a recess in the dielectric layer.

In some aspects, the techniques described herein relate to a semiconductor structure, wherein the dielectric layer is further disposed on the substrate below a source feature and a channel region of the MOS device and isolates the source feature and the channel region from the substrate.

In some aspects, the techniques described herein relate to a semiconductor structure, further including: a first backside power rail and a first backside VIA that connect to the drain feature through salicide formed in a recess in the dielectric layer; and a second backside power rail and a second backside VIA that connect to the source feature through salicide formed in a second recess in the dielectric layer.

In some aspects, the techniques described herein relate to a semiconductor structure, wherein the dielectric layer includes a first depth below a source feature and the drain feature that is larger than a second depth of the dielectric layer below a channel region of the MOS device.

In some aspects, the techniques described herein relate to a semiconductor structure, wherein: the MOS device includes a gate-all-around (GAA) device; the dielectric layer has a first layer that extends a first thickness below a bottom metal gate of the GAA device; and the dielectric layer has a second layer above the first layer with a second thickness that extends to a top surface of the bottom metal gate of the GAA device.

In some aspects, the techniques described herein relate to a semiconductor structure, wherein: the MOS device includes a FinFET device; the dielectric layer has a first layer that extends a first thickness below a channel region of the FinFET device; and the dielectric layer has a second layer above the first layer with a second thickness that extends along sidewalls of the channel region.

In some aspects, the techniques described herein relate to a semiconductor structure, wherein: the MOS device includes a planar device; the dielectric layer has a first layer that extends a first thickness below a channel region of the planar device; and the dielectric layer has a second layer above the first layer with a second thickness that extends along sidewalls of the channel region.

In some aspects, the techniques described herein relate to a method, including: forming a dielectric layer on a substrate; forming an active region of a MOS device; forming a sacrificial gate structure of the MOS device; forming a source feature and a drain feature of the MOS device, wherein the drain feature is formed above the dielectric layer; replacing the sacrificial gate structure with a replacement metal gate; and forming a first backside power rail and a first backside VIA that connect to the drain feature through salicide formed in a recess in the dielectric layer; wherein the dielectric layer isolates the drain feature from the substrate.

In some aspects, the techniques described herein relate to a method, wherein forming the dielectric layer on the substrate includes: etching a trench in a core region of a substrate or an SRAM region of the substrate; filling the trench with a dielectric material; planarizing a surface of the dielectric material to be coplanar with a surface of the substrate; and bonding a wafer over the surface of the substrate that is coplanar with the surface of the dielectric material.

In some aspects, the techniques described herein relate to a method, wherein forming the source feature and the drain feature include forming the source feature and the drain feature over the dielectric layer.

In some aspects, the techniques described herein relate to a method, wherein replacing the sacrificial gate structure with the replacement metal gate includes forming the replacement metal gate over the dielectric layer.

In some aspects, the techniques described herein relate to a method, wherein forming the first backside power rail and the first backside VIA that connect to the drain feature through salicide formed in the recess in the dielectric layer includes: forming the recess in the dielectric layer; forming the salicide in the recess; forming the first backside VIA through the recess that connects to the drain feature through the salicide formed in the recess; and forming the first backside power rail that connects to the first backside VIA.

In some aspects, the techniques described herein relate to a method, further including: forming a second recess in the dielectric layer; forming salicide in the second recess; forming second backside VIA through the second recess that connects to the source feature through the salicide formed in the second recess; and forming a second backside power rail that connects to the second backside VIA.

In some aspects, the techniques described herein relate to a method, wherein forming the dielectric layer on the substrate includes: forming a first layer of the dielectric layer before forming the sacrificial gate structure; and forming a second layer of the dielectric layer after forming the sacrificial gate structure.

In some aspects, the techniques described herein relate to a method, wherein forming the dielectric layer on the substrate includes: forming a first layer of the dielectric layer; and forming a second layer of the dielectric layer over a portion but not all of the first layer of the dielectric layer before forming the active region of the MOS device.

In some aspects, the techniques described herein relate to a semiconductor structure, including: a source feature, a drain feature, and a metal gate of a MOS device disposed above a substrate; a dielectric layer disposed on the substrate and below the drain feature, wherein the dielectric layer isolates the drain feature from the substrate; and a backside power rail and a backside VIA that connect to the drain feature through salicide in a recess in the dielectric layer.

In some aspects, the techniques described herein relate to a semiconductor structure, wherein: the MOS device includes a gate-all-around (GAA) device; the dielectric layer has a first layer that extends a first thickness below a bottom metal gate of the GAA device; and the dielectric layer has a second layer above the first layer with a second thickness that extends to a top surface of the bottom metal gate of the GAA device.

In some aspects, the techniques described herein relate to a semiconductor structure, wherein: the MOS device includes a FinFET device; the dielectric layer has a first layer that extends a first thickness below a channel region of the FinFET device; and the dielectric layer has a second layer above the first layer with a second thickness that extends along sidewalls of the channel region.

In some aspects, the techniques described herein relate to a semiconductor structure, wherein: the MOS device includes a planar device; the dielectric layer has a first layer that extends a first thickness below a channel region of the planar device; and the dielectric layer has a second layer above the first layer with a second thickness that extends along sidewalls of the channel region.

While at least one exemplary embodiment has been presented in the foregoing detailed description of the disclosure, it should be appreciated that a vast number of variations exist. It should also be appreciated that the exemplary embodiment or exemplary embodiments are only examples, and are not intended to limit the scope, applicability, or configuration of the disclosure in any way. Rather, the foregoing detailed description will provide those skilled in the art with a convenient road map for implementing an exemplary embodiment of the disclosure. It being understood that various changes may be made in the function and arrangement of elements described in an exemplary embodiment without departing from the scope of the disclosure as set forth in the appended claims.

What is claimed is:

1. A semiconductor structure, comprising:
a dielectric layer disposed on a substrate below a drain feature of a MOS device;
wherein the dielectric layer isolates the drain feature from the substrate.

2. The semiconductor structure of claim 1, further comprising a backside power rail and a backside VIA that connect to the drain feature through salicide formed in a recess in the dielectric layer.

3. The semiconductor structure of claim 1, wherein the dielectric layer is further disposed on the substrate below a source feature and a channel region of the MOS device and isolates the source feature and the channel region from the substrate.

4. The semiconductor structure of claim 3, further comprising:
a first backside power rail and a first backside VIA that connect to the drain feature through salicide formed in a recess in the dielectric layer; and
a second backside power rail and a second backside VIA that connect to the source feature through salicide formed in a second recess in the dielectric layer.

5. The semiconductor structure of claim 1, wherein the dielectric layer comprises a first depth below a source feature and the drain feature that is larger than a second depth of the dielectric layer below a channel region of the MOS device.

6. The semiconductor structure of claim 5, wherein:
the MOS device comprises a gate-all-around (GAA) device;
the dielectric layer has a first layer that extends a first thickness below a bottom metal gate of the GAA device; and
the dielectric layer has a second layer above the first layer with a second thickness that extends to a top surface of the bottom metal gate of the GAA device.

7. The semiconductor structure of claim 5, wherein:
the MOS device comprises a FinFET device;
the dielectric layer has a first layer that extends a first thickness below a channel region of the FinFET device; and
the dielectric layer has a second layer above the first layer with a second thickness that extends along sidewalls of the channel region.

8. The semiconductor structure of claim 5, wherein:
the MOS device comprises a planar device;
the dielectric layer has a first layer that extends a first thickness below a channel region of the planar device; and
the dielectric layer has a second layer above the first layer with a second thickness that extends along sidewalls of the channel region.

9. A method, comprising:
forming a dielectric layer on a substrate;
forming an active region of a MOS device;
forming a sacrificial gate structure of the MOS device;
forming a source feature and a drain feature of the MOS device, wherein the drain feature is formed above the dielectric layer;
replacing the sacrificial gate structure with a replacement metal gate; and
forming a first backside power rail and a first backside VIA that connect to the drain feature through salicide formed in a recess in the dielectric layer;
wherein the dielectric layer isolates the drain feature from the substrate.

10. The method of claim 9, wherein forming the dielectric layer on the substrate comprises:
etching a trench in a core region of a substrate or an SRAM region of the substrate;
filling the trench with a dielectric material;
planarizing a surface of the dielectric material to be coplanar with a surface of the substrate; and
bonding a wafer over the surface of the substrate that is coplanar with the surface of the dielectric material.

11. The method of claim 9, wherein forming the source feature and the drain feature comprise forming the source feature and the drain feature over the dielectric layer.

12. The method of claim 9, wherein replacing the sacrificial gate structure with the replacement metal gate comprises forming the replacement metal gate over the dielectric layer.

13. The method of claim 9, wherein forming the first backside power rail and the first backside VIA that connect to the drain feature through salicide formed in the recess in the dielectric layer comprises:
forming the recess in the dielectric layer;
forming the salicide in the recess;
forming the first backside VIA through the recess that connects to the drain feature through the salicide formed in the recess; and
forming the first backside power rail that connects to the first backside VIA.

14. The method of claim 13, further comprising:
forming a second recess in the dielectric layer;
forming salicide in the second recess;
forming second backside VIA through the second recess that connects to the source feature through the salicide formed in the second recess; and
forming a second backside power rail that connects to the second backside VIA.

15. The method of claim 9, wherein forming the dielectric layer on the substrate comprises:
forming a first layer of the dielectric layer before forming the sacrificial gate structure; and
forming a second layer of the dielectric layer after forming the sacrificial gate structure.

16. The method of claim 9, wherein forming the dielectric layer on the substrate comprises:
forming a first layer of the dielectric layer; and
forming a second layer of the dielectric layer over a portion but not all of the first layer of the dielectric layer before forming the active region of the MOS device.

17. A semiconductor structure, comprising:
a source feature, a drain feature, and a metal gate of a MOS device disposed above a substrate;
a dielectric layer disposed on the substrate and below the drain feature, wherein the dielectric layer isolates the drain feature from the substrate; and
a backside power rail and a backside VIA that connect to the drain feature through salicide in a recess in the dielectric layer.

18. The semiconductor structure of claim 17, wherein:
the MOS device comprises a gate-all-around (GAA) device;
the dielectric layer has a first layer that extends a first thickness below a bottom metal gate of the GAA device; and
the dielectric layer has a second layer above the first layer with a second thickness that extends to a top surface of the bottom metal gate of the GAA device.

19. The semiconductor structure of claim 17, wherein:
the MOS device comprises a FinFET device;
the dielectric layer has a first layer that extends a first thickness below a channel region of the FinFET device; and
the dielectric layer has a second layer above the first layer with a second thickness that extends along sidewalls of the channel region.

20. The semiconductor structure of claim 17, wherein:
the MOS device comprises a planar device;
the dielectric layer has a first layer that extends a first thickness below a channel region of the planar device; and
the dielectric layer has a second layer above the first layer with a second thickness that extends along sidewalls of the channel region.
